(19) United States
(12) Patent Application Publication
(10) Pub. No.: US 2019/0031822 A1
(43) Pub. Date: Jan. 31, 2019

(54) RESIN COMPOSITION AND MULTILAYER SUBSTRATE

(71) Applicant: SEKISUI CHEMICAL CO., LTD., Osaka-City, Osaka (JP)

(72) Inventors: Tatsushi Hayashi, Tsukuba-city, Ibaraki (JP); Susumu Baba, Tsukuba-city, Ibaraki (JP)

(21) Appl. No.: 16/067,606

(22) PCT Filed: Mar. 28, 2017
(86) PCT No.: PCT/JP2017/012593

§ 371 Date: Jun. 30, 2018

(30) Foreign Application Priority Data
Mar. 28, 2016 (JP) 2016-063324

(51) Int. Cl. C08G 61/10; C08L 63/00; H05K 1/03

(52) U.S. Cl. CPC C08G 61/10; C08L 63/00; H05K 3/4644; H05K 2201/0129; H05K 2201/0154; H05K 1/0373

(57) ABSTRACT

There is provided a resin composition with which the desmear properties can be enhanced, a cured product thereof can be made low in dielectric loss tangent, and the cured product can be made high in heat resistance. The resin composition according to the present invention includes a compound having a structure represented by formula (1), a structure in which a substituent is bonded to a benzene ring in the structure represented by formula (1), a structure represented by formula (2), a structure in which a substituent is bonded to a benzene ring in the structure represented by formula (2), a structure represented by formula (3), a structure in which a substituent is bonded to a benzene ring in the structure represented by formula (3), a structure represented by formula (4), or a structure in which a substituent is bonded to a benzene ring in the structure represented by formula (4) and an active ester compound and the structure represented by the formula (1), (2), (3), or (4) has a phenylene group or a naphthylene group and a hetero atom, a group in which a hydrogen atom is bonded to a hetero atom, or a carbonyl group.

### TECHNICAL FIELD

The present invention relates to a resin composition used for forming an insulating layer, for example, in a multilayer substrate or the like. Moreover, the present invention relates to a multilayer substrate prepared with the resin composition.

### BACKGROUND

For the purpose of obtaining electronic parts such as a laminated plate and a printed wiring board, various resin compositions have hitherto been used. For example, in a multilayer printed wiring board, for the purposes of forming an insulating layer by which insulation between layers in the inside thereof is attained and forming an insulating layer positioned at a surface layer portion thereof, the resin composition has been used. On a surface of the insulating layer, wiring lines, which are generally made of a metal, are layered. Moreover, for the purpose of forming an insulating layer, a B-stage film, which is prepared by forming the resin composition into a film, is sometimes used. The resin composition and the B-stage film have been used as insulating materials for printed wiring boards including a build-up film.

As an example of the resin composition, the following Patent Document 1 discloses a curable epoxy composition including an epoxy compound, an active ester compound, and a filling material.

### RELATED ART DOCUMENT

Patent Document

Patent Document 1: JP 2015-143302 A

### SUMMARY OF THE INVENTION

### Problems to be Solved by the Invention

Since an active ester compound is included in the composition described in Patent Document 1, the dielectric loss tangent of a cured product of the composition can be lowered to some extent. However, a cured product of the composition described in Patent Document 1 sometimes becomes low in heat resistance.

Moreover, at the time of forming an insulating layer in a printed wiring board, a B-stage film is laminated on a member to be laminated such as an inner layer circuit substrate or the like by the use of a vacuum laminator or by being pressed. Afterward, a process for forming a metal wiring line, a process for curing an insulating film, a process for forming a via hole in the insulating film, a desmearing process for the via hole, and the like are performed to produce a printed wiring board.

When the composition described in Patent Document 1 is used, a smear at the bottom of a via hole sometimes fails to be efficiently removed by a desmearing treatment.

Moreover, for the purpose of reducing transmission loss, the insulating layer is required to have a low dielectric loss tangent.

There is a case where, by selecting the kind of the epoxy compound, heat resistance can be heightened to some extent or desmear properties can be enhanced to some extent. However, only by the selection of the epoxy compound, it is difficult to simultaneously achieve all of satisfactory desmear properties, low dielectric loss tangent of a cured product, and high heat resistance of the cured product.

Even when a conventional composition for forming an insulating layer is used, it is difficult to simultaneously achieve all of satisfactory desmear properties, low dielectric loss tangent of a cured product, and high heat resistance of the cured product.

An object of the present invention is to provide a resin composition with which the desmear properties can be enhanced, a cured product thereof can be made low in dielectric loss tangent, and the cured product can be made high in heat resistance. Moreover, the present invention provides a multilayer substrate prepared with the resin composition.

### Means for Solving the Problems

According to a broad aspect of the present invention, there is provided a resin composition including a compound having a structure represented by the following formula (1), a structure in which a substituent is bonded to a benzene ring in the structure represented by the following formula (1), a structure represented by the following formula (2), a structure in which a substituent is bonded to a benzene ring in the structure represented by the following formula (2), a structure represented by the following formula (3), a structure in which a substituent is bonded to a benzene ring in the structure represented by the following formula (3), a structure represented by the following formula (4), or a structure in which a substituent is bonded to a benzene ring in the structure represented by the following formula (4) and an active ester compound.

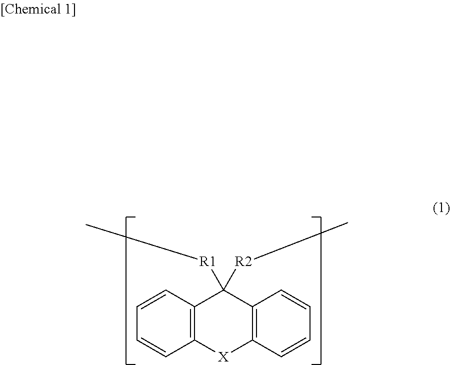

In the formula (1), R1 and R2 each represent a phenylene group or a naphthylene group and X represents a hetero atom, a group in which a hydrogen atom is bonded to a hetero atom, or a carbonyl group.

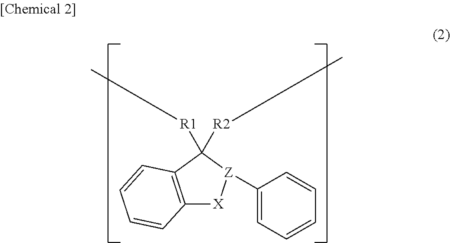

In the formula (2), R1 and R2 each represent a phenylene group or a naphthylene group, X represents a hetero atom, a group in which a hydrogen atom is bonded to a hetero atom, or a carbonyl group, and Z represents a CH group or an N group.

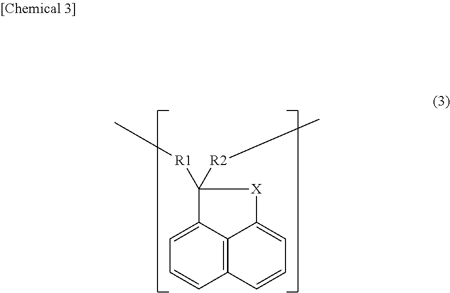

In the formula (3), R1 and R2 each represent a phenylene group or a naphthylene group and X represents a hetero atom, a group in which a hydrogen atom is bonded to a hetero atom, or a carbonyl group.

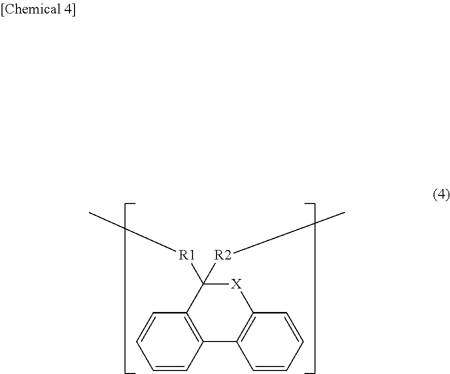

In the formula (4), R1 and R2 each represent a phenylene group or a naphthylene group and X represents a hetero atom, a group in which a hydrogen atom is bonded to a hetero atom, or a carbonyl group.

In a specific aspect of the resin composition according to the present invention, the compound having a structure represented by the formula (1), a structure in which a substituent is bonded to a benzene ring in the structure represented by the formula (1), a structure represented by the formula (2), a structure in which a substituent is bonded to a benzene ring in the structure represented by the formula (2), a structure represented by the formula (3), a structure in which a substituent is bonded to a benzene ring in the structure represented by the formula (3), a structure represented by the formula (4), or a structure in which a substituent is bonded to a benzene ring in the structure represented by the formula (4) has an epoxy group within a moiety other than the structure represented by the formula (1), a moiety other than the structure in which a substituent is bonded to a benzene ring in the structure represented by the formula (1), a moiety other than the structure represented by the formula (2), a moiety other than the structure in which a substituent is bonded to a benzene ring in the structure represented by the formula (2), a moiety other than the structure represented by the formula (3), a moiety other than the structure in which a substituent is bonded to a benzene ring in the structure represented by the formula (3), a moiety other than the structure represented by the formula (4), or a moiety other than the structure in which a substituent is bonded to a benzene ring in the structure represented by the formula (4).

In a specific aspect of the resin composition according to the present invention, the total content of the compound having a structure represented by the formula (1), a structure in which a substituent is bonded to a benzene ring in the structure represented by the formula (1), a structure represented by the formula (2), a structure in which a substituent is bonded to a benzene ring in the structure represented by the formula (2), a structure represented by the formula (3), a structure in which a substituent is bonded to a benzene ring in the structure represented by the formula (3), a structure represented by the formula (4), or a structure in which a substituent is bonded to a benzene ring in the structure represented by the formula (4) is 20% by weight or less in 100% by weight of ingredients excluding an inorganic filling material and a solvent from ingredients for the resin composition.

In a specific aspect of the resin composition according to the present invention, the compound having a structure represented by the formula (1), a structure in which a substituent is bonded to a benzene ring in the structure represented by the formula (1), a structure represented by the formula (2), a structure in which a substituent is bonded to a benzene ring in the structure represented by the formula (2), a structure represented by the formula (3), a structure in which a substituent is bonded to a benzene ring in the structure represented by the formula (3), a structure represented by the formula (4), or a structure in which a substituent is bonded to a benzene ring in the structure represented by the formula (4) is a compound having a structure represented by the formula (1), a structure represented by the formula (2), a structure represented by the formula (3), or a structure represented by the formula (4).

In specific aspect of the resin composition according to the present invention, the resin composition includes an inorganic filling material.

In a specific aspect of the resin composition according to the present invention, the resin composition includes a thermoplastic resin.

In a specific aspect of the resin composition according to the present invention, the thermoplastic resin is a polyimide resin having an aromatic skeleton.

In a specific aspect of the resin composition according to the present invention, the active ester compound has a naphthalene ring within a moiety other than the terminal.

According to a broad aspect of the present invention, there is provided a multilayer substrate including a circuit substrate and an insulating layer arranged on the circuit substrate, the insulating layer being a cured product of the above-described resin composition.

### Effect of the Invention

Since the resin composition according to the present invention includes a compound having a structure represented by the formula (1), a structure in which a substituent is bonded to a benzene ring in the structure represented by the formula (1), a structure represented by the formula (2), a structure in which a substituent is bonded to a benzene ring in the structure represented by the formula (2), a structure represented by the formula (3), a structure in which a substituent is bonded to a benzene ring in the structure represented by the formula (3), a structure represented by the formula (4), or a structure in which a substituent is bonded to a benzene ring in the structure represented by the formula (4) and an active ester compound, the desmear properties can be enhanced, cured product thereof can be made low in dielectric loss tangent, and the cured product can be made high in heat resistance.

### BRIEF DESCRIPTION OF DRAWING

FIG. 1 is a sectional view schematically showing a multilayer substrate prepared with the resin composition in accordance with one embodiment of the present invention.

### MODE(S) FOR CARRYING OUT THE INVENTION

Hereinafter, the present invention will be described in detail.

The resin composition according to the present invention includes a compound having a structure represented by the following formula (1), a structure in which a substituent is bonded to a benzene ring in the structure represented by the following formula (1) (hereinafter, sometimes described as a structure represented by the formula (1-1)), a structure represented by the following formula (2), a structure in which a substituent is bonded to a benzene ring in the structure represented by the following formula (2) (hereinafter, sometimes described as a structure represented by the formula (2-1)), a structure represented by the following formula (3), a structure in which a substituent is bonded to a benzene ring in the structure represented by the following formula (3) (hereinafter, sometimes described as a structure represented by the formula (3-1)), a structure represented by the following formula (4), or a structure in which a substituent is bonded to a benzene ring in the structure represented by the following formula (4) (hereinafter, sometimes described as a structure represented by the formula (4-1)) and an active ester compound. In the present invention, a compound having a structure represented by the formula (1) may be used, a compound having a structure represented by the formula (1-1) may be used, a compound having a structure represented by the formula (2) may be used, a compound having a structure represented by the formula (2-1) may be used, a compound having a structure represented by the formula (3) may be used, a compound having a structure represented by the formula (3-1) may be used, a compound having a structure represented by the formula (4) may be used, and a compound having a structure represented by the formula (4-1) may be used. In the present invention, one kind of compound of the compound having a structure represented by the formula (1), the compound having a structure represented by the formula (1-1), the compound having a structure represented by the formula (2), the compound having a structure represented by the formula (2-1), the compound having a structure represented by the formula (3), the compound having a structure represented by the formula (3-1), the compound having a structure represented by the formula (4), and the compound having a structure represented by the formula (4-1) may be used alone and two or more kinds of compounds thereof may be used in combination. Having a certain degree of steric hindrance effect is common among the compounds having a structure represented by the formula (1), (1-1), (2), (2-1), (3), (3-1), (4), or (4-1) and having a hetero atom, a group in which a hydrogen atom is bonded to a hetero atom, or a carbonyl group is also common among those.

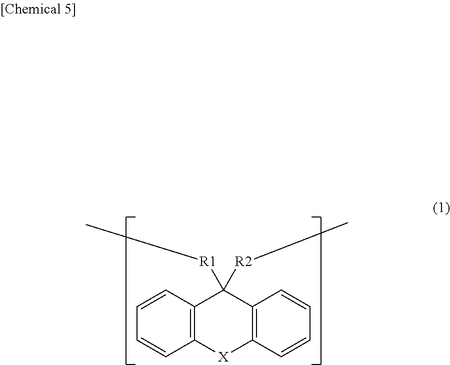

In the foregoing formula (1), R1 and R2 each represent a phenylene group or a naphthylene group and X represents a hetero atom, a group in which a hydrogen atom is bonded to a hetero atom, or a carbonyl group. In the formula (1), each of two solid lines drawn at the right end part and the left end part corresponds to a binding site with another group.

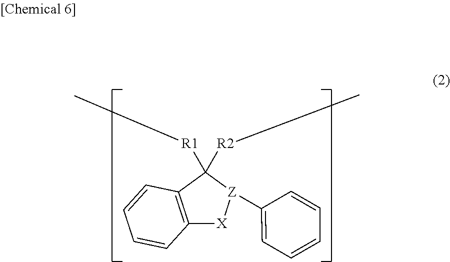

In the foregoing formula (2), R1 and R2 each represent a phenylene group or a naphthylene group, X represents a hetero atom, a group in which a hydrogen atom is bonded to a hetero atom, or a carbonyl group, and Z represents a CH group or an N group. In the formula (2), each of two solid lines drawn at the right end part and the left end part corresponds to a binding site with another group.

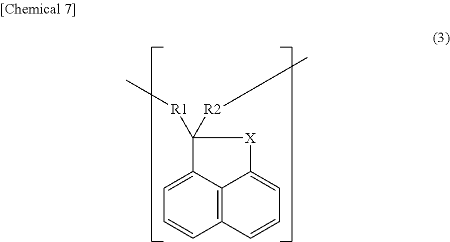

In the foregoing formula (3), R1 and R2 each represent a phenylene group or a naphthylene group and X represents a hetero atom, a group in which a hydrogen atom is bonded to a hetero atom, or a carbonyl group. In the formula (3), each of two solid lines drawn at the right end part and the left end part corresponds to a binding site with another group.

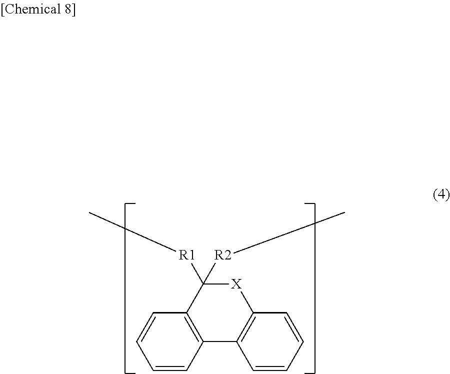

In the foregoing formula (4), R1 and R2 each represent a phenylene group or a naphthylene group and X represents a hetero atom, a group in which a hydrogen atom is bonded to a hetero atom, or a carbonyl group. In the formula (4), each of two solid lines drawn at the right end part and the left end part corresponds to a binding site with another group.

Since the resin composition according to the present invention is provided with the above-mentioned configuration, the desmear properties can be enhanced, a cured product thereof can be made low in dielectric loss tangent, and the cured product can be made high in heat resistance. At the time of forming an insulating layer, a smear can be effectively removed when a via hole is formed and subjected to a desmearing treatment.

In the present invention, it is possible to simultaneously achieve all of satisfactory desmear properties, low dielectric loss tangent of a cured product, and high heat resistance of the cured product.

In the present invention, it has been found out that, in order to simultaneously achieve all of satisfactory desmear properties, low dielectric loss tangent of a cured product, and high heat resistance of the cured product, a compound having a structure represented by the formula (1), (1-1), (2), (2-1), (3), (3-1), (4), or (4-1) and an active ester compound need only to be combined to be used.

In the foregoing formulas (1), (1-1), (2), (2-1), (3), (3-1), (4), and (4-1), examples of the hetero atom or the group in which a hydrogen atom is bonded to a hetero atom include an NH group, an O group, an S group, and the like.

From the viewpoints of making the steric hindrance effect by a substituent small and facilitating the synthesis, in the formulas (1-1), (2-1), (3-1), and (4-1), examples of the substituent bonded to a benzene ring include a halogen atom and a hydrocarbon group. It is preferred that the substituent be a halogen atom or a hydrocarbon group. It is preferred that the halogen atom as the substituent be a fluorine atom. The number of carbon atoms of the hydrocarbon group as the substituent is preferably 12 or less, more preferably 6 or less, and further preferably 4 or less.

From the viewpoints of eliminating the steric hindrance effect by a substituent and facilitating the synthesis, it is preferred that the compound having a structure represented by the foregoing formula (1), (1-1), (2), (2-1), (3), (3-1), (4), or (4-1) be a compound having a structure represented by the foregoing formula (1), (2), (3), or (4).

It is preferred that the structure represented by the foregoing formula (1) (including a structural portion excluding the substituent from the structure represented by the foregoing formula (1-1)) be the structure represented by the following formula (1A), the following formula (1B), or the following formula (1C) and it is more preferred that the structure represented by the foregoing formula (1) be the structure represented by the following formula (1A) or the following formula (1B), because effects of the present invention are effectively exerted.

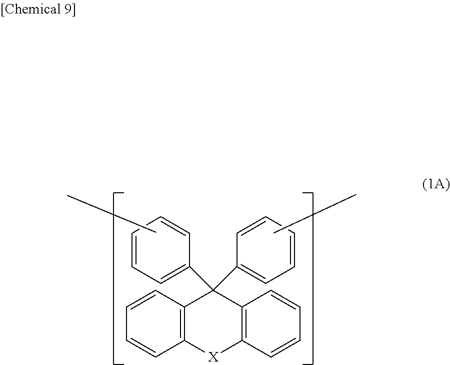

In the foregoing formula (1A), X represents a hetero atom, a group in which a hydrogen atom is bonded to a hetero atom, or a carbonyl group.

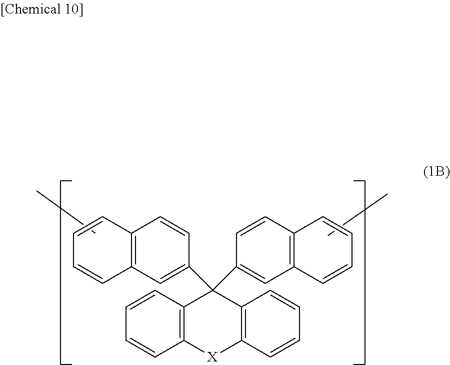

In the foregoing formula (1B), X represents a hetero atom, a group in which a hydrogen atom is bonded to a hetero atom, or a carbonyl group.

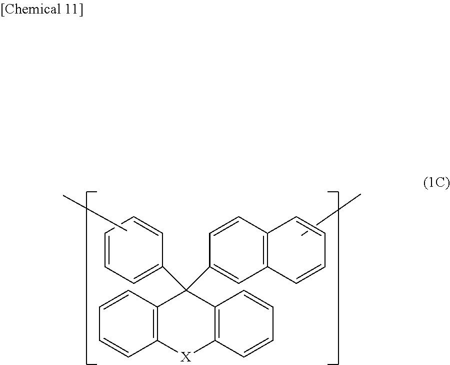

In the foregoing formula (1C), X represents a hetero atom, a group in which a hydrogen atom is bonded to a hetero atom, or a carbonyl group.

It is preferred that the structure represented by the foregoing formula (2) (including a structural portion excluding the substituent from the structure represented by the foregoing formula (2-1)) be the structure represented by the following formula (2A), the following formula (2B), or the following formula (2C) and it is more preferred that the structure represented by the foregoing formula (2) be the structure represented by the following formula (2A) or the following formula (2B), because effects of the present invention are effectively exerted.

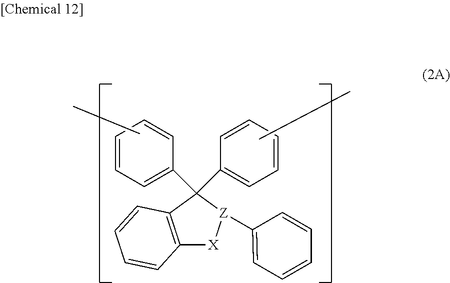

In the foregoing formula (2A), X represents a hetero atom, a group in which a hydrogen atom is bonded to a hetero atom, or a carbonyl group and Z represents a CH group or an N group.

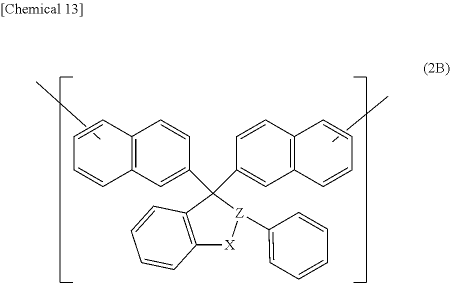

In the foregoing formula (2B), X represents a hetero atom, a group in which a hydrogen atom is bonded to a hetero atom, or a carbonyl group and Z represents a CH group or an N group.

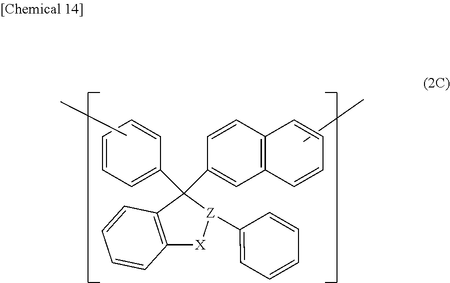

In the foregoing formula (2C), X represents a hetero atom, a group in which a hydrogen atom is bonded to a hetero atom, or a carbonyl group and Z represents a CH group or an N group.

It is preferred that the structure represented by the foregoing formula (3) (including a structural portion excluding the substituent from the structure represented by the foregoing formula (3-1)) be the structure represented by the following formula (3A), the following formula (3B), or the following formula (3C) and it is more preferred that the structure represented by the foregoing formula (3) be the structure represented by the following formula (3A) or the following formula (3B), because effects of the present invention are effectively exerted.

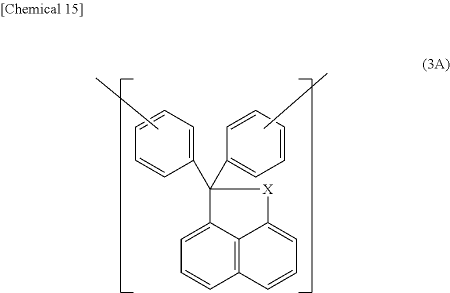

In the foregoing formula (3A), X represents a hetero atom, a group in which a hydrogen atom is bonded to a hetero atom, or a carbonyl group.

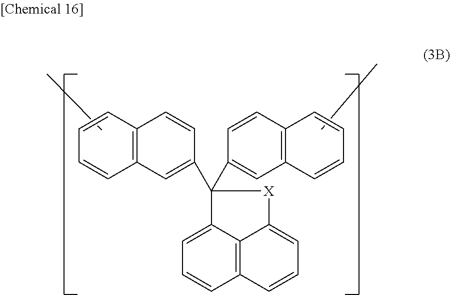

In the foregoing formula (3B), X represents a hetero atom, a group in which a hydrogen atom is bonded to a hetero atom, or a carbonyl group.

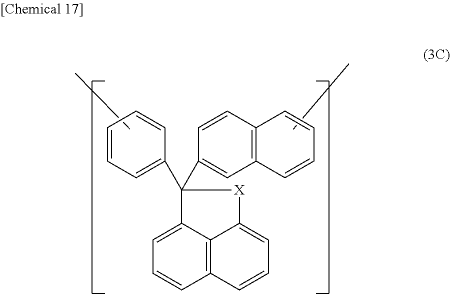

In the foregoing formula (3C), X represents a hetero atom, a group in which a hydrogen atom is bonded to a hetero atom, or a carbonyl group.

It is preferred that the structure represented by the foregoing formula (4) (including a structural portion excluding the substituent from the structure represented by the foregoing formula (4-1)) be the structure represented by the following formula (4A), the following formula (4B), or the following formula (4C) and it is more preferred that the structure represented by the foregoing formula (4) be the structure represented by the following formula (4A) or the following formula (4B), because effects of the present invention are effectively exerted.

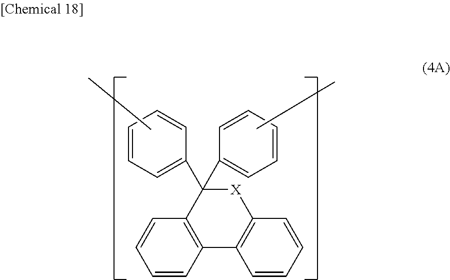

In the foregoing formula (4A), X represents a hetero atom, a group in which a hydrogen atom is bonded to a hetero atom, or a carbonyl group.

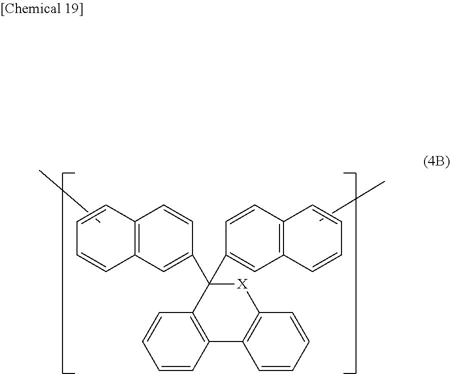

In the foregoing formula (4B), X represents a hetero atom, a group in which a hydrogen atom is bonded to a hetero atom, or a carbonyl group.

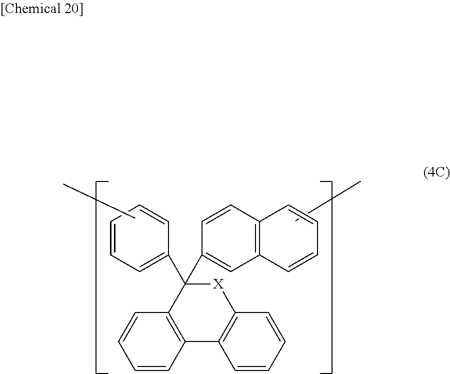

In the foregoing formula (4C), X represents a hetero atom, a group in which a hydrogen atom is bonded to a hetero atom, or a carbonyl group.

It is preferred that the compound having a structure represented by the foregoing formula (1), (1-1), (1A), (1B), (10), (2), (2-1), (2A), (2B), (20), (3), (3-1), (3A), (3B), (3C), (4), (4-1), (4A), (4B), or (4C) be a thermosetting compound and it is preferred that the compound having the structure be an epoxy compound, because effects of the present invention are further satisfactorily exerted. It is preferred that the compound having a structure represented by the foregoing formula (1), (1-1), (1A), (1B), (10), (2), (2-1), (2A), (2B), (2C), (3), (3-1), (3A), (3B), (3C), (4), (4-1), (4A), (4B), or (4C) have an epoxy group within a moiety other than the structure represented by the foregoing formula (1), (1-1), (1A), (1B), (10), (2), (2-1), (2A), (2B), (2C), (3), (3-1), (3A), (3B), (3C), (4), (4-1), (4A), (4B), or (4C) and it is more preferred that the compound having the structure have a glycidyl group within the moiety other than the structure, because effects of the present invention are further satisfactorily exerted. That is, in the case of a compound having a structure represented by the foregoing formula (1), it is preferred that the compound having a structure represented by the foregoing formula (1) have an epoxy group within a moiety other than the structure represented by the foregoing formula (1) and it is more preferred that the compound having the structure have a glycidyl group within the moiety other than the structure. The moiety other than the structure represented by the foregoing formula (1) refers to each of two moieties respectively bonded at the right end part and the left end part in the formula (1). The same holds true for the case of a compound having a structure represented by the formula other than the formula (1).

In the structure represented by the foregoing formula (1), (1-1), (1A), (1B), (10), (2), (2-1), (2A), (2B), (2C), (3), (3-1), (3A), (3B), (3C), (4), (4-1), (4A), (4B), or (4C), X may represent a hetero atom, may represent a group in which a hydrogen atom is bonded to a hetero atom, and may represent a carbonyl group, because effects of the present invention are further satisfactorily exerted.

When X represents a hetero atom in the structure represented by the foregoing formula (1), (1-1), (1A), (1B), (10), (2), (2-1), (2A), (2B), (2C), (3), (3-1), (3A), (3B), (3C), (4), (4-1), (4A), (4B), or (4C), it is preferred that X represent an oxygen atom, because effects of the present invention are further satisfactorily exerted.

It is preferred that a group as the moiety other than the structure represented by the foregoing formula (1), (1-1), (1A), (1B), (10), (2), (2-1), (2A), (2B), (2C), (3), (3-1), (3A), (3B), (3C), (4), (4-1), (4A), (4B), or (4C) (each of two groups respectively bonded at the left end part and the right end part (in the formula)) be a glycidyl ether group and it is preferred that the group be a group represented by the following formula (11), because effects of the present invention are further satisfactorily exerted. It is preferred that the compound having a structure represented by the foregoing formula (1), (1-1), (1A), (1B), (10), (2), (2-1), (2A), (2B), (2C), (3), (3-1), (3A), (3B), (3C), (4), (4-1), (4A), (4B), or (4C) have a glycidyl ether group, it is preferred that the compound have a group represented by the following formula (11), it is more preferred that the compound have plural glycidyl ether groups, and it is more preferred that the compound have plural groups represented by the following formula (11).

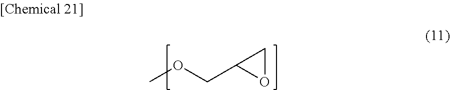

In 100% by weight of ingredients excluding an inorganic filling material and a solvent from ingredients for the resin composition, the total content of the compound having a structure represented by the foregoing formula (1), (1-1), (2), (2-1), (3), (3-1), (4), or (4-1) is preferably 3% by weight or more, more preferably 5% by weight or more, further preferably 10% by weight or more, preferably 99% by weight or less, more preferably 80% by weight or less, further preferably 50% by weight or less, and most preferably 20% by weight or less. Moreover, in 100% by weight of ingredients excluding an inorganic filling material and a solvent from ingredients for the resin composition, the total content of the compound having a structure represented by the foregoing formula (1), (2), (3), or (4) is preferably 3% by weight or more, more preferably 5% by weight or more, further preferably 10% by weight or more, preferably 99% by weight or less, more preferably 80% by weight or less, further preferably 50% by weight or less, and most preferably 20% by weight or less. When the total content of the compound having a structure represented by the foregoing formula (1), (1-1), (2), (2-1), (3), (3-1), (4), or (4-1) is the above lower limit or more and the above upper limit or less, effects of the present invention are further satisfactorily exerted and the heat resistance, dielectric characteristics, and desmear properties are further enhanced.

One hundred percent by weight of ingredients excluding an inorganic filling material and a solvent from ingredients for the resin composition means, when an inorganic filling material is included in the resin composition and no solvent is included therein, 100% by weight of ingredients excluding the inorganic filling material from ingredients for the resin composition, when no inorganic filling material is included in the resin composition and a solvent is included therein, 100% by weight of ingredients excluding the solvent from ingredients for the resin composition, and when no inorganic filling material and no solvent are included in the resin composition, 100% by weight of ingredients for the resin composition.

It is preferred that the resin composition include an inorganic filling material. It is preferred that the resin composition include a thermoplastic resin. It is preferred that the resin composition include a curing accelerator. The resin composition may include a solvent.

Hereinafter, the details of each ingredient used for the resin composition according to the present invention, applications of the resin composition according to the present invention, and the like will be described.

[Thermosetting Compound]

It is preferred that the resin composition include a thermosetting compound. As the thermosetting compound, a conventionally known thermosetting compound is usable. Examples of the thermosetting compound include an oxetane compound, an epoxy compound, an episulfide compound, a (meth)acrylic compound, a phenol compound, an amino compound, an unsaturated polyester compound, a polyurethane compound, a silicone compound, a polyimide compound, and the like. One kind of the thermosetting compound may be used alone and two or more kinds thereof may be used in combination.

It is preferred that the thermosetting compound be an epoxy compound. The epoxy compound refers to an organic compound having at least one epoxy group. One kind of the epoxy compound may be used alone and two or more kinds thereof may be used in combination.

Examples of the epoxy compound include a bisphenol A type epoxy compound, a bisphenol F type epoxy compound, a bisphenol S type epoxy compound, a phenol novolac type epoxy compound, a biphenyl type epoxy compound, a biphenyl novolac type epoxy compound, a biphenol type epoxy compound, a naphthalene type epoxy compound, a fluorene type epoxy compound, a phenol aralkyl type epoxy compound, a naphthol aralkyl type epoxy compound, a dicyclopentadiene type epoxy compound, an anthracene type epoxy compound, an epoxy compound having an adamantane skeleton, an epoxy compound having a tricyclodecane skeleton, an epoxy compound having a triazine nucleus in its skeleton, and the like. From the viewpoint of further improving the dielectric characteristics of a cured product of the resin composition and the adhesive properties between the cured product and a metal layer, it is preferred that the epoxy compound be a biphenyl novolac type epoxy compound. From the viewpoint of further improving the desmear properties, the dielectric characteristics of a cured product of the resin composition, and the adhesive properties between the cured product and metal layer, it is preferred that the epoxy compound be an aminophenol type epoxy compound.

The resin composition may include a thermosetting compound different from the compound having a structure represented by the formula (1), (1-1), (2), (2-1), (3), (3-1), (4), or (4-1).

It is preferred that the compound having a structure represented by the foregoing formula (1), (1-1), (2), (2-1), (3), (3-1), (4), or (4-1) be a thermosetting compound and it is more preferred that the compound having the structure be an epoxy compound.

From the viewpoint of obtaining a resin composition further excellent in preservation stability, the molecular weight of the thermosetting compound is preferably less than 10000 and more preferably less than 5000. When the thermosetting compound is not a polymer and when the structural formula of the thermosetting compound can be specified, the molecular weight thereof means a molecular weight that can be calculated from its structural formula. Moreover, when the thermosetting compound is a polymer, the molecular weight thereof means a weight average molecular weight.

In 100% by weight of ingredients excluding an inorganic filling material and a solvent from ingredients for the resin composition, the total content of the thermosetting compound and a curing agent is preferably 20% by weight or more, more preferably 40% by weight or more, preferably 99% by weight or less, and more preferably 95% by weight or less. When the total content of the thermosetting compound and a curing agent is the above lower limit or more and the above upper limit or less, a further satisfactory cured product is obtained.

[Curing Agent]

As examples of a curing agent, a cyanate ester compound (a cyanate ester curing agent), a phenol compound (a phenol curing agent), an amine compound (an amine curing agent), a thiol compound (a thiol curing agent), an imidazole compound, a phosphine compound, an acid anhydride, an active ester compound, dicyandiamide, and the like exist.

In the present invention, an active ester compound is used as the curing agent. An active ester compound and a curing agent other than the active ester compound may be used in combination.

The active ester compound refers to a compound containing at least one ester bond in its structural body and having two aromatic rings respectively bonded to both sides of the ester bond. For example, the active ester compound is obtained by a condensation reaction of a carboxylic acid compound or a thiocarboxylic acid compound with a hydroxy compound or a thiol compound. Examples of the active ester compound include a compound represented by the following formula (21).

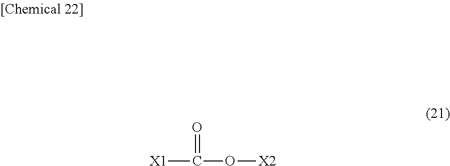

In the foregoing formula (21), X1 and X2 each represent a group containing an aromatic ring. Preferred examples of the group containing an aromatic ring include a benzene ring which may have a substituent, a naphthalene ring which may have a substituent, and the like. Examples of the substituent include a halogen atom and a hydrocarbon group. It is preferred that the substituent be a halogen atom or a hydrocarbon group. It is preferred that the halogen atom as the substituent be a chlorine atom. The number of carbon atoms of the hydrocarbon group is preferably 12 or less, more preferably 6 or less, and further preferably 4 or less.

Examples of the combination of X1 and X2 include the combination of a benzene ring which may have a substituent and a benzene ring which may have a substituent, the combination of a benzene ring which may have a substituent and a naphthalene ring which may have a substituent, and the combination of a naphthalene ring which may have a substituent and a naphthalene ring which may have a substituent. From the viewpoint of further improving the dielectric characteristics of a cured product of the resin composition and the adhesive properties between the cured product and a metal layer, it is preferred that the active ester compound have a naphthalene ring within a moiety other than the terminal. From the viewpoint of further improving the dielectric characteristics of a cured product of the resin composition and the adhesive properties between the cured product and a metal layer, it is preferred that the active ester compound have a naphthalene ring in its main chain. The active ester compound having a naphthalene ring within a moiety other than the terminal or in its main chain may also have a naphthalene ring at the terminal. From the viewpoint of further improving the dielectric characteristics of a cured product of the resin composition and the adhesive properties between the product and a metal layer, as the combination of groups in the active ester compound, preferred is the combination of a benzene ring which may have a substituent and a naphthalene ring which may have a substituent and more preferred is the combination of a naphthalene ring which may have a substituent and a naphthalene ring which may have a substituent.

The active ester compound is not particularly limited. Examples of a commercial product of the active ester compound include “HPC-8000-65T” and “EXB-9416-70BK” available from DIC Corporation, and the like.

The content of the curing agent is appropriately selected so that the thermosetting compound is satisfactorily cured. In 100% by weight of ingredients excluding an inorganic filling material and a solvent from ingredients for the resin composition, the content of the whole curing agent is preferably 20% by weight or more, more preferably 30% by weight or more, preferably 80% by weight or less, and more preferably 70% by weight or less. In 100% by weight of ingredients excluding an inorganic filling material and a solvent from ingredients for the resin composition, the content of the active ester compound is preferably 15% by weight or more, more preferably 20% by weight or more, preferably 70% by weight or less, and more preferably 65% by weight or less. When the content of the active ester compound is the above lower limit or more and the above upper limit or less, a further satisfactory cured product is obtained and the dielectric loss tangent is effectively lowered.

[Thermoplastic Resin]

Examples of the thermoplastic resin include a polyvinyl acetal resin, a phenoxy resin, a polyimide resin, and the like. One kind of the thermoplastic resin may be used alone and two or more kinds thereof may be used in combination.

From the viewpoint of effectively making the dielectric loss tangent low and effectively enhancing the adhesive properties of a metal wiring line irrespective of the curing condition, it is preferred that the thermoplastic resin be a phenoxy resin or a polyimide resin. The thermoplastic resin may be a phenoxy resin and may be a polyimide resin. By the use of a phenoxy resin and a polyimide resin, deterioration in the embeddability of a resin film into a hole in a circuit substrate or irregularities on a circuit substrate and inhomogeneous distribution of an inorganic filling material are suppressed. Moreover, by the use of a phenoxy resin and a polyimide resin, dispersibility of an inorganic filling material is improved because the melt viscosity can be adjusted and a resin composition or a B-stage film becomes difficult to flow and is hardly spread toward an unintended area in a curing process. By the use of a polyimide resin, the dielectric loss tangent can be still further effectively lowered. Each of the phenoxy resin and the polyimide resin to be included in the resin composition is not particularly limited. As the phenoxy resin and the polyimide resin, a conventionally known phenoxy resin and a conventionally known polyimide resin are usable, respectively. One kind of each of the phenoxy resin and the polyimide resin may be used alone and two or more kinds thereof may be used in combination.

From the viewpoints of further heightening the compatibility between the thermoplastic resin and another ingredient (for example, a thermosetting compound) and further improving the adhesive properties between a cured product of the resin composition and a metal layer, it is preferred that the thermoplastic resin have an aromatic skeleton, it is preferred that the thermoplastic resin be a polyimide resin, and it is more preferred that the thermoplastic resin be a polyimide resin having an aromatic skeleton.

Examples of the phenoxy resin include a phenoxy resin having a skeleton such as a skeleton of the bisphenol A type, a skeleton of the bisphenol F type, a skeleton of the bisphenol S type, a biphenyl skeleton, a novolac skeleton, a naphthalene skeleton, and an imide skeleton, and the like.

Examples of a commercial product of the phenoxy resin include “YP50”, “YP55”, and “YP70” available from NIPPON STEEL & SUMIKIN CHEMICAL CO., LTD., “1256B40”, “4250”, “4256H40”, “4275”, “YX6954-BH30”, and “YX8100BH30” available from Mitsubishi Chemical Corporation, and the like.

Examples of the polyimide resin include a polyimide resin having a skeleton of the bisphenol A type, a skeleton of the bisphenol F type, a skeleton of the bisphenol S type, a biphenyl skeleton, a novolac skeleton, or a naphthalene skeleton, and the like.

Examples of a commercial product of the polyimide resin include “HR001”, “HR002”, and “HR003” available from SONAR Corporation, “SN-20” available from New Japan Chemical Co., Ltd., “PI-1” and “PI-2” available from T&K TOKA CO., LTD., and the like.

From the viewpoint of obtaining a resin composition further excellent in preservation stability, the weight average molecular weight of the thermoplastic resin, for example, each of the phenoxy resin and the polyimide resin, is preferably 5000 or more, more preferably 10000 or more, preferably 100000 or less, and more preferably 50000 or less.

The weight average molecular weight of the thermoplastic resin, for example, each of the phenoxy resin and the polyimide resin, refers to a weight average molecular weight, calculated on the polystyrene equivalent basis, measured by gel permeation chromatography (GPC).

The content of the thermoplastic resin, for example, each of the phenoxy resin and the polyimide resin, is not particularly limited. In 100% by weight of ingredients excluding an inorganic filling material and a solvent from ingredients for the resin composition, the content of the thermoplastic resin, for example, each of the phenoxy resin and the polyimide resin, is preferably 1% by weight or more, more preferably 4% by weight or more, preferably 15% by weight or less, and more preferably 10% by weight or less. When the content of the thermoplastic resin, for example, each of the phenoxy resin and the polyimide resin, is the above lower limit or more and the above upper limit or less, the embeddability of a resin composition or a B-stage film into a hole in a circuit substrate or irregularities on a circuit substrate is improved. When the content of the thermoplastic resin, for example, each of the phenoxy resin and the polyimide resin, is the above lower limit or more, the resin composition becomes further easy to be formed into a film and a further satisfactory insulating layer is obtained. The surface roughness of a surface of a cured product of the resin composition is further made small and the adhesive strength between the cured product and a metal layer is further heightened.

[Inorganic Filling Material]

It is preferred that the resin composition include an inorganic filling material. By the use of an inorganic filling material, the dimensional change by heat of a cured product of the resin composition is further made small. Moreover, the dielectric loss tangent of the cured product is further made small.

Examples of the inorganic filling material include silica, talc, clay, mica, hydrotalcite, alumina, magnesium oxide, aluminum hydroxide, aluminum nitride, boron nitride, and the like.

From the viewpoints of making the surface roughness of a surface of a cured product of the resin composition small, further heightening the adhesive strength between the cured product and a metal layer, forming a finer wiring line on a surface of the cured product, and imparting the cured product with more satisfactory insulation reliability, it is preferred that the inorganic filling material be silica or alumina, it is more preferred that the inorganic filling material be silica, and it is further preferred that the inorganic filling material be fused silica. By the use of silica, the coefficient of thermal expansion of the cured product is further lowered, the surface roughness of a surface of the cured product is effectively made small, and the adhesive strength between the cured product and a metal layer is effectively heightened. It is preferred that the shape of a silica particle be a spherical shape.

The average particle diameter of the inorganic filling material is preferably 10 nm or more, more preferably 50 nm or more, further preferably 150 nm or more, preferably 20 μm or less, more preferably 10 μm or less, further preferably 5 μm or less, and especially preferably 1 μm or less. When the average particle diameter of the inorganic filling material is the above lower limit or more and the above upper limit or less, the size of a hole formed by a roughening treatment or the like is made fine and the number of holes is increased. As a result, the adhesive strength between the cured product and a metal layer is further heightened.

As the average particle diameter of the inorganic filling material, a value of the median diameter (d50), which is read at a point where the volumetric integrated value becomes 50% in a particle size distribution, is adopted. The average particle diameter can be measured with the use of a laser diffraction scattering type particle size distribution measuring apparatus.

It is preferred that particles of the inorganic filling material have a spherical shape and it is more preferred that the inorganic filling material be spherical silica. In this case, the surface roughness of a surface of the cured product is effectively made small, and furthermore, the adhesive strength between an insulating layer and a metal layer is effectively heightened. When particles of the inorganic filling material have a spherical shape, the aspect ratio of particles of the inorganic filling material is preferably 2 or less and more preferably 1.5 or less.

It is preferred that the inorganic filling material be subjected to a surface treatment, it is more preferred that the inorganic filling material be a processed product surface-treated with a coupling agent, and it is further preferred that the inorganic filling material be a processed product surface-treated with a silane coupling agent. Therefore, the surface roughness of a surface of a roughened cured product is further made small, the adhesive strength between the cured product and a metal layer is further heightened, a finer wiring line is formed on a surface of the cured product, and the cured product can be imparted with further satisfactory insulation reliability between wiring lines and insulation reliability between layers.

Examples of the coupling agent include a silane coupling agent, a titanium coupling agent, an aluminum coupling agent, and the like. Examples of the silane coupling agent include methacrylsilane, acrylsilane, aminosilane, imidazolesilane, vinylsilane, epoxysilane, and the like.

In 100% by weight of ingredients excluding a solvent from ingredients for the resin composition, the content of the inorganic filling material is preferably 25% by weight or more, more preferably 30% by weight or more, further preferably 40% by weight or more, especially preferably 50% by weight or more, most preferably 60% by weight or more, preferably 99% by weight or less, more preferably 85% by weight or less, further preferably 80% by weight or less, and especially preferably 75% by weight or less. When the total content of the inorganic filling material is the above lower limit or more and the above upper limit or less, while the adhesive strength between a cured product of the resin composition and a metal layer is further heightened and a finer wiring line is formed on a surface of the cured product, if the inorganic filling material amount falls within this range, it is also possible to make the dimensional change by heat of the cured product small.

[Curing Accelerator]

It is preferred that the resin composition include a curing accelerator. By the use of the curing accelerator, the curing rate is further increased. By quickly curing a resin film, the number of unreacted functional groups is decreased, and consequently, the crosslinking density becomes high. The curing accelerator is not particularly limited and a conventionally known curing accelerator is usable. One kind of the curing accelerator may be used alone and two or more kinds thereof may be used in combination.

Examples of the curing accelerator include an imidazole compound, a phosphorus compound, an amine compound, an organometallic compound, and the like.

Examples of the imidazole compound include 2-undecylimidazole, 2-heptadecylimidazole, 2-methylimidazole, 2-ethyl-4-methylimidazole, 2-phenylimidazole, 2-phenyl-4-methylimidazole, 1-benzyl-2-methylimidazole, 1-benzyl-2-phenylimidazole, 1,2-dimethylimidazole, 1-cyanoethyl-2-methylimidazole, 1-cyanoethyl-2-ethyl-4-methylimidazole, 1-cyanoethyl-2-undecylimidazole, 1-cyanoethyl-2-phenylimidazole, 1-cyanoethyl-2-undecylimidazolium trimellitate, 1′-cyanoethyl-2-phenylimidazolium trimellitate, 2,4′-diamino-6-[2′-methylimidazolyl-(1′)]-ethyl-s-triazine, 2,4′-diamino-6-[2′-undecylimidazolyl-(1′)]-ethyl-s-triazine, 2,4′-diamino-6-[2′-ethyl-4′-methylimidazolyl-(1′)]-ethyl-s-triazine, 2,4′-diamino-6-[2′-methylimidazolyl-(1′)]-ethyl-s-triazine isocyanuric acid adduct, 2-phenylimidazole isocyanuric acid adduct, 2-methylimidazole isocyanuric acid adduct, 2′-phenyl-4,5-dihydroxymethylimidazole, 2-phenyl-4-methyl-5-dihydroxymethylimidazole, and the like.

Examples of the phosphorus compound include triphenylphosphine and the like.

Examples of the amine compound include diethylamine, triethylamine, diethylenetetramine, triethylenetetramine, 4,4-dimethylaminopyridine, and the like.

Examples of the organometallic compound include zinc naphthenate, cobalt naphthenate, tin octylate, cobalt octylate, bis(acetylacetonato)cobalt(II), tris(acetylacetonato)cobalt(III), and the like.

The content of the curing accelerator is not particularly limited. In 100% by weight of ingredients excluding an inorganic filling material and a solvent from ingredients for the resin composition, the content of the curing accelerator is preferably 0.01% by weight or more, more preferably 0.9% by weight or more, preferably 5.0% by weight or less, and more preferably 3.0% by weight or less. When the content of the curing accelerator is the above lower limit or more and the above upper limit or less, the resin composition is efficiently cured. The more the content of the curing accelerator lies within a preferred range, the more the preservation stability of the resin composition is heightened and the more satisfactory the resulting cured product becomes.

[Solvent]

The resin composition includes no solvent or includes a solvent. By the use of the solvent, the viscosity of a resin composition can be controlled within a suitable range and the coating properties of the resin composition can be enhanced. Moreover, the solvent may be used for obtaining slurry containing the inorganic filling material. One kind of the solvent may be used alone and two or more kinds thereof may be used in combination.

Examples of the solvent include acetone, methanol, ethanol, butanol, 2-propanol, 2-methoxyethanol, 2-ethoxyethanol, 1-methoxy-2-propanol, 2-acetoxy-1-methoxypropane, toluene, xylene, methyl ethyl ketone, N,N-dimethylformamide, methyl isobutyl ketone, N-methyl-pyrrolidone, n-hexane, cyclohexane, cyclohexanone, naphtha being a mixture, and the like.

It is preferred that most of the solvent be removed at the time of forming the resin composition into a film. Accordingly, the boiling point of the solvent is preferably 200° C. or less and more preferably 180° C. or less. The content of a solvent in the resin composition is not particularly limited. In view of the coating properties of the resin composition and the like, the content of the solvent can be appropriately set to a prescribed value.

[Other Ingredients]

For the purpose of improvement in impact resistance, heat resistance, compatibility among ingredients in a resin composition, usability, and the like, a leveling agent, a flame retardant, a coupling agent, a coloring agent, an oxidation inhibitor, an ultraviolet ray deterioration-preventing agent, a defoaming agent, a thickener, a thixotropy-imparting agent, an additional thermosetting resin other than the epoxy compound, and the like may be added to the resin composition.

Examples of the coupling agent include a silane coupling agent, a titanium coupling agent, an aluminum coupling agent, and the like. Examples of the silane coupling agent include vinylsilane, aminosilane, imidazolesilane, epoxysilane, and the like.

Examples of the additional thermosetting resin include a polyphenylene ether resin, a divinyl benzyl ether resin, a polyarylate resin, a diallylphthalate resin, a thermosetting polyimide resin, a benzoxazine resin, a benzoxazole resin, a bismaleimide resin, an acrylate resin, and the like.

(Resin Film (B-Stage Film) and Laminated Film)

The above-described resin composition is formed into a film to obtain a resin film (B-stage film). It is preferred that the resin film be a B-stage film.

From the viewpoint of further uniformly controlling the curing degree of a resin film, the thickness of the resin film is preferably 5 μm or more and preferably 200 μm or less.

Examples of a method of forming the resin composition into a film include an extrusion molding method in which a resin composition is melt-kneaded with the use of an extruder to be extruded and then formed into a film by the use of a T die or a circular die, a casting molding method in which a solvent-containing resin composition is cast and formed into a film, a conventionally known molding method of a film other than those, and the like. An extrusion molding method or a casting molding method is preferred because the method is capable of coping with the thickness reduction. A sheet is included in the film.

The resin composition is formed into a film and the film can be subjected to drying by heating, for example, at 50 to 150° C. for 1 to 10 minutes, to such an extent that the curing by heat is not excessively advanced to obtain a resin film being a B-stage film.

A film-shaped resin composition that can be obtained by being subjected to the drying process described above is referred to as a B-stage film. The B-stage film is a film-shaped resin composition being in a semi-cured state. A semi-cured product thereof is not in a completely-cured state and the curing can be further advanced.

The resin film may be constituted of a material not being a prepreg. When the resin film is constituted of a material not being a prepreg, no migration occurs along the glass cloth or the like. Moreover, at the time of subjecting a resin film to lamination or precuring, no irregularities attributed to the glass cloth are generated on its surface. The resin composition can be suitably used to form a laminated film provided with a sheet of metal foil or a base material and a resin film layered on a surface of the sheet of metal foil or the base material. The resin film in the laminated film is formed of the resin composition. It is preferred that the sheet of metal foil be a sheet of copper foil.

Examples of the base material of the laminated film include polyester resin films such as a polyethylene terephthalate film and a polybutylene terephthalate film, olefin resin films such as a polyethylene film and a polypropylene film, a polyimide resin film, and the like. A surface of the base material may be subjected to a release treatment, as necessary.

When each of the resin composition and the resin film is used to prepare an insulating layer for a circuit, it is preferred that the thickness of the insulating layer formed of the resin composition or the resin film be equal to or more than the thickness of a conductor layer (metal layer) forming the circuit. The thickness of the insulating layer is preferably 5 μm or more and preferably 200 μm or less.

(Printed Wiring Board)

The resin composition and the resin film are suitably used to form an insulating layer in a printed wiring board.

For example, the resin film is heated and pressure-molded to obtain the printed wiring board.

A sheet of metal foil can be layered on one face or both faces of the resin film. A method of layering a sheet of metal foil on the resin film is not particularly limited and a known method can be used. For example, with the use of a parallel flat plate press machine or a roll laminator, the resin film can be layered on a sheet of metal foil with heating or without heating while being pressed.

(Copper-Clad Laminated Plate and Multilayer Substrate)

The resin composition and the resin film are suitably used to obtain a copper-clad laminated plate. One example of the copper-clad laminated plate includes a copper-clad laminated plate provided with a sheet of copper foil and a resin film layered on one surface of the sheet of copper foil. The resin film of this copper-clad laminated plate is formed of the resin composition.

The thickness of the sheet of copper foil of the copper-clad laminated plate is not particularly limited. It is preferred that the thickness of the sheet of copper foil lie within the range of 1 to 50 μm. Moreover, in order to heighten adhesive between an insulating layer prepared by curing the resin film and a sheet of copper foil, it is preferred that the sheet of copper foil have fine recesses and protrusions on its surface. A method of forming recesses and protrusions is not particularly limited. Examples of the method of forming recesses and protrusions include a forming method in which a sheet of copper foil is treated with a known chemical liquid, and the like.

The resin composition and the resin film are suitably used to obtain a multilayer substrate. It is preferred that the resin composition and the resin film be used to form an insulating layer in a printed wiring board. One example of the multilayer substrate includes a multilayer substrate provided with a circuit substrate and an insulating layer layered on the circuit substrate. When a resin film prepared by forming the resin composition into a film is adopted, the insulating layer of this multilayer substrate is formed of the resin film. Moreover, when a laminated film is adopted, the insulating layer of the multilayer substrate may be formed of the resin film of the laminated film. It is preferred that the insulating layer be layered on a surface of a circuit substrate portion and on a surface of a circuit portion provided on the circuit substrate. It is preferred that a portion of the insulating layer be embedded between the circuit portions.

In the multilayer substrate, it is preferred that a surface of the insulating layer at the opposite side of the surface on which the circuit substrate is layered be subjected to a roughening treatment.

As a roughening treatment method, a conventionally known roughening treatment method can be used and the roughening treatment method is not particularly limited. The surface of the insulating layer may be subjected to a swelling treatment before subjected to a roughening treatment.

Moreover, it is preferred that the multilayer substrate be further provided with a copper plating layer layered on a roughening-treated surface of the insulating layer.

Moreover, another example of the multilayer substrate includes a multilayer substrate provided with a circuit substrate, an insulating layer layered on a surface of the circuit substrate, and a sheet of copper foil layered on a surface of the insulating layer at the opposite side of the surface on which the circuit substrate is layered. It is preferred that, when a copper-clad laminated plate provided with a sheet of copper foil and a resin film layered on one surface of the sheet of copper foil is adopted, the resin film be cured to form the insulating layer and the sheet of copper foil. Furthermore, it is preferred that the sheet of copper foil be subjected to an etching treatment to constitute a copper circuit.

Another example of the multilayer substrate includes a multilayer substrate provided with a circuit substrate and plural insulating layers layered on top of one another on the surface of the circuit substrate. At least one layer among the plural layers of insulating layers arranged on the circuit substrate is formed of a resin film prepared by forming the resin composition into a film. It is preferred that the multilayer substrate be further provided with a circuit to be layered on at least one surface of the insulating layer formed of the resin film.

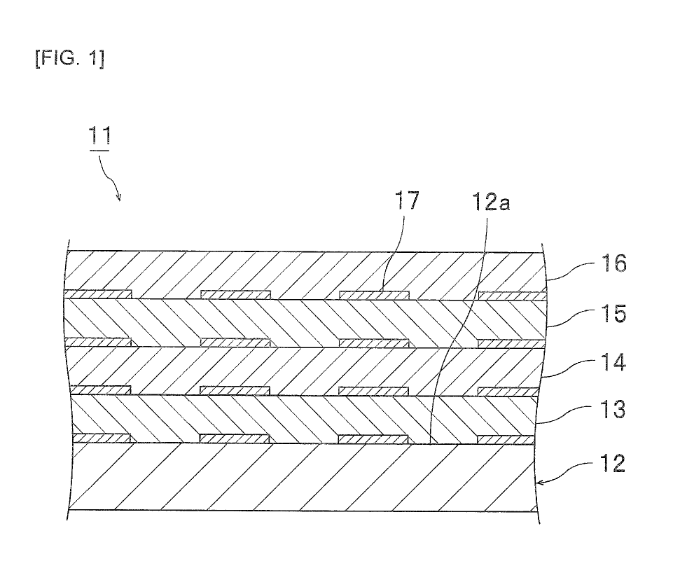

FIG. 1 is a sectional view schematically showing a multilayer substrate prepared with the resin composition in accordance with one embodiment of the present invention.

In a multilayer substrate 11 shown in FIG. 1, plural layers of insulating layers 13 to 16 are layered on top of one another on an upper face 12a of a circuit substrate 12. The insulating layers 13 to 16 are cured product layers. A metal layer 17 is formed in a partial region of the upper face 12a of the circuit substrate 12. With regard to insulating layers 13 to 15 among plural layers of insulating layers 13 to 16, a metal layer 17 is formed in a partial region of the respective upper faces of the insulating layers 13 to 15 other than the insulating layer 16 positioned on an outer surface opposite to the circuit substrate 12 side. The metal layer 17 constitutes a circuit. Respective metal layers 17 are arranged between the circuit substrate 12 and the insulating layer 13 and between respective layers of the insulating layers 13 to 16 layered on top of one another. A metal layer 17 arranged at the lower side and a metal layer 17 arranged at the upper side are connected to each other by means of at least one of a via-hole connection and a through-hole connection which are not illustrated.

In the multilayer substrate 11, the insulating layers 13 to 16 are formed of the resin composition. In the present embodiment, micropores not illustrated are formed on respective surfaces of the insulating layers 13 to 16 because the respective surfaces of the insulating layers 13 to 16 have been subjected to roughening treatment. Moreover, a portion of the metal layer 17 extends to the inside of the micropore. Moreover, in the multilayer substrate 11, a dimension (L) in width direction of the metal layer 17 and a dimension (S) in width direction of a portion in which no metal layer 17 is formed can be made small. Moreover, in the multilayer substrate 11, satisfactory insulation reliability is imparted between a metal layer arranged at the upper side and a metal layer arranged at the lower side which are not connected to each other neither by a via-hole connection not illustrated nor by a through-hole connection not illustrated.

(Roughening Treatment and Swelling Treatment)

It is preferred that the resin composition be used to obtain a cured product to be subjected to a roughening treatment or a desmearing treatment. Examples of the cured product also include a preliminarily cured product capable of being further cured.

In order to form fine recesses and protrusions on the surface of a cured product obtained by preliminarily curing the resin composition, it is preferred that the cured product be subjected to a roughening treatment. It is preferred that the cured product be subjected to a swelling treatment before subjected to a roughening treatment. It is preferred that the cured product be subjected to a swelling treatment after preliminarily cured and before subjected to a roughening treatment and be further cured after subjected to the roughening treatment. However, the cured product may not necessarily be subjected to a swelling treatment.

As a method for the swelling treatment, for example, a method of treating a cured product with an aqueous solution or an organic solvent dispersion of a compound composed mainly of ethylene glycol or the like is used. A swelling liquid used in the swelling treatment generally contains an alkali as a pH adjusting agent or the like. It is preferred that the swelling liquid contain sodium hydroxide. Specifically, for example, with the use of a 40% by weight aqueous ethylene glycol solution or the like, a cured product is treated at a treatment temperature of 30 to 85° C. for 1 to 30 minutes to perform the swelling treatment. It is preferred that the temperature for the swelling treatment lie within the range of 50 to 85° C. When the temperature for the swelling treatment is too low, a long period of time is required for the swelling treatment, and furthermore, there is a tendency for the adhesive strength between a cured product and a metal layer to be lowered.

In the roughening treatment, for example, a chemical oxidizing agent such as a manganese compound, a chromium compound, or a persulfuric acid compound and the like are used. These chemical oxidizing agents are added with water or an organic solvent to be used as an aqueous solution or an organic solvent dispersion thereof. A roughening liquid used in the roughening treatment generally contains an alkali as a pH adjusting agent or the like. It is preferred that the roughening liquid contain sodium hydroxide.

Examples of the manganese compound include potassium permanganate, sodium permanganate, and the like. Examples of the chromium compound include potassium dichromate, anhydrous potassium chromate, and the like. Examples of the persulfuric acid compound include sodium persulfate, potassium persulfate, ammonium persulfate, and the like.

A method for the roughening treatment is not particularly limited. As a method for the roughening treatment, for example, a method of treating a cured product under conditions of a treatment temperature of 30 to 85° C. and a time period of 1 to 30 minutes with the use of a 30 to 90 g/L permanganic acid or permanganate solution and a 30 to 90 g/L sodium hydroxide solution is suitable. It is preferred that the temperature for the roughening treatment lie within the range of 50 to 85° C. It is preferred that the number of times of the roughening treatment be set to one time or two times.

The arithmetic average roughness Ra on the surface of a cured product is preferably 10 nm or more and is preferably less than 300 nm, more preferably less than 200 nm, and further preferably less than 100 nm. In this case, the adhesive strength between the cured product and a metal layer or a wiring line is heightened, and furthermore, a finer wiring line is formed on the surface of an insulating layer. Furthermore, it is possible to suppress the conductor loss and it is possible to suppress the signal loss low.

(Desmearing Treatment)

In a cured product obtained by preliminarily curing the resin composition, a penetration hole is sometimes formed. In the multilayer substrate and the like, a via hole, a through hole, or the like is formed as the penetration hole. For example, a via hole can be formed by irradiation of a laser beam such as a CO₂ laser beam. The diameter of a via hole is not particularly limited and is 60 to 80 μm or so. Due to the formation of the penetration hole, a smear being a resin residue derived from a resin component contained in the cured product is often formed at the bottom part in a via hole.

In order to remove the smear, it is preferred that the surface of a cured product be subjected to a desmearing treatment. The desmearing treatment also sometimes functions as a roughening treatment.

In the desmearing treatment, as in the case of the roughening treatment, for example, a chemical oxidizing agent such as a manganese compound, a chromium compound, or a persulfuric acid compound and the like are used. These chemical oxidizing agents are added with water or an organic solvent to be used as an aqueous solution or an organic solvent dispersion thereof. A desmearing treatment liquid used in the desmearing treatment generally contains an alkali. It is preferred that the desmearing treatment liquid contain sodium hydroxide.

A method for the desmearing treatment is not particularly limited. As a method for the desmearing for example, a method of treating a cured product one time or two times under conditions of a treatment temperature of 30 to 85° C. and a time period of 1 to 30 minutes with the use of a 30 to 90 g/L permanganic acid or permanganate solution and a 30 to 90 g/L sodium hydroxide solution is suitable. It is preferred that the temperature for the desmearing treatment lie within the range of 50 to 85° C.

By the use of the resin composition, the surface roughness on the surface of a desmearing-treated cured product is sufficiently made small.

Hereinafter, the present invention will be described in detail with reference to examples and comparative examples. The present invention is not limited to the following examples.

The following ingredients were used.

### (Synthesis Example 1) Synthesis of Compound (51)

Thirty seven and six tenths grams/0.4 mol of phenol (a phenolic compound) and 20.8 g/0.1 mol of anthraquinone (an aromatic carbonyl compound) were mixed and heated to about 60° C. to be melted, after which 0.1 ml of sulfuric acid, 0.8 ml of 3-mercaptopropionic acid, and 10 ml of toluene were added thereto and the contents were allowed to undergo a reaction with stirring. After confirmation of the conversion of anthraquinone, the contents were added with 100 ml of toluene and cooled and a precipitated solid was filtered off with suction. Afterward, the solid was stirred in hot water at 60° C. to be washed therewith and recrystallization was performed to obtain an intermediate compound. Next, 0.5 g of an intermediate compound, 1.8 g (92.5 mmol) of epichlorohydrin, and 0.73 g of 2-propanol were placed in a vessel and the temperature of the contents was elevated to 40° C. to prepare a homogeneous solution, after which 0.32 g of a 48.5% by weight aqueous sodium hydroxide solution was added dropwise to the homogeneous solution over a period of 90 minutes. The temperature of the contents was gradually elevated during the dropping so that the internal temperature of the vessel becomes 65° C. after the completion of dropping and the contents were stirred for 30 minutes. Then, from the reaction product, excess epichlorohydrin and 2-propanol were distilled off under reduced pressure and an aimed product was dissolved in 2 g of methyl isobutyl ketone, added with 0.02 g of a 48.5% by weight aqueous sodium hydroxide solution, and stirred for 1 hour at 65° C. Afterward, an aqueous sodium primary phosphate solution was added to the reaction liquid to neutralize excess sodium hydroxide and the contents were washed with water to remove a by-product salt. Next, methyl isobutyl ketone was completely removed, and finally, reduced pressure drying was performed to obtain a compound (Compound (51)) having a structure represented by the following formula (51).

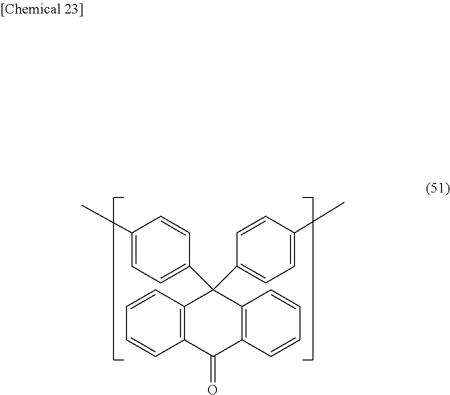

A group as the moiety other than the structure represented by the foregoing formula (51) (each of two groups respectively bonded at the both end parts (in the formula)) is a group represented by the foregoing formula (11).

### (Synthesis Examples 2 to 9) Synthesis of Compounds (52) to (59)

With regard to compounds (Compounds (52) to (59)) having a structure represented by each of the following formulas raw materials described in the following Table 1 were used and allowed to undergo a reaction in the same manner as that in Synthesis Example 1 to obtain respective aimed products.

TABLE 1

| Synthesis | | | Phenolic |
|---|---|---|---|
| Example | Compound | Aromatic carbonyl compound | compound |
| 1 | 51 | Anthraquinone | Phenol |
| 2 | 52 | 9(10H)-Acridone | Phenol |
| 3 | 53 | 9,10-Phenanthrenequinone | Phenol |
| 4 | 54 | Acenaphthenequinone | Phenol |
| 5 | 55 | N-Phenylphthalimide | Phenol |
| 6 | 56 | N-Phenylphthalimide | 2-Naphthol |
| 7 | 57 | Anthrone | Phenol |
| 8 | 58 | 9-Fluorenone | Phenol |
| 9 | 59 | 9-Fluorenone | 2-Naphthol |

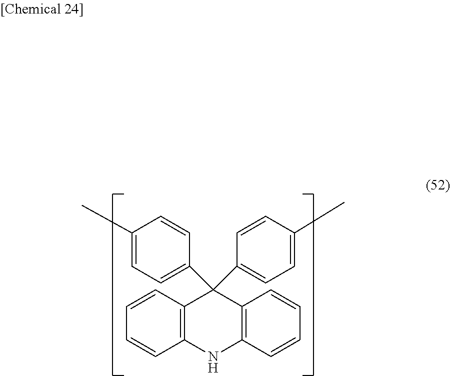

A group as the moiety other than the structure represented by the foregoing formula (52) (each of two groups respectively bonded at the both end parts (in the formula)) is a group represented by the foregoing formula (11).

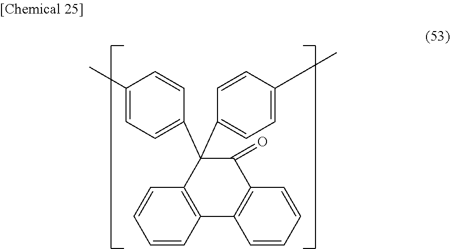

A group as the moiety other than the structure represented by the foregoing formula (53) (each of two groups respectively bonded at the both end parts (in the formula)) is a group represented by the foregoing formula (11).

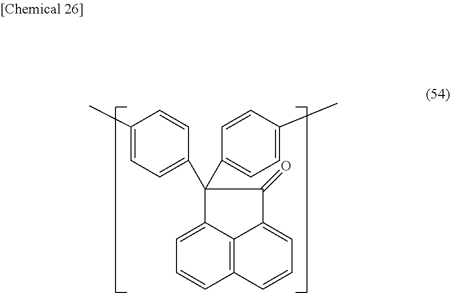

A group as the moiety other than the structure represented by the foregoing formula (54) (each of two groups respectively bonded at the both end parts (in the formula)) is a group represented by the foregoing formula (11).

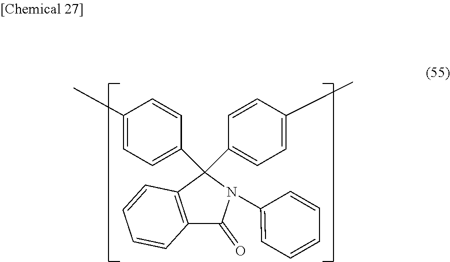

A group as the moiety other than the structure represented by the foregoing formula (55) (each of two groups respectively bonded at the both end parts (in the formula)) is a group represented by the foregoing formula (11).

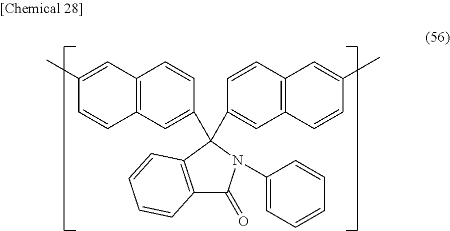

A group as the moiety other than the structure represented by the foregoing formula (56) (each of two groups respectively bonded at the both end parts (in the formula)) is a group represented by the foregoing formula (11).

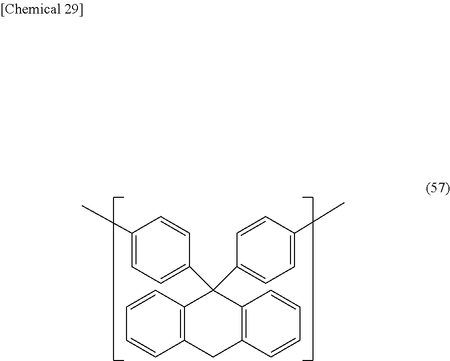

A group as the moiety other than the structure represented by the foregoing formula (57) (each of two groups respectively bonded at the both end parts (in the formula)) is a group represented by the foregoing formula (11).

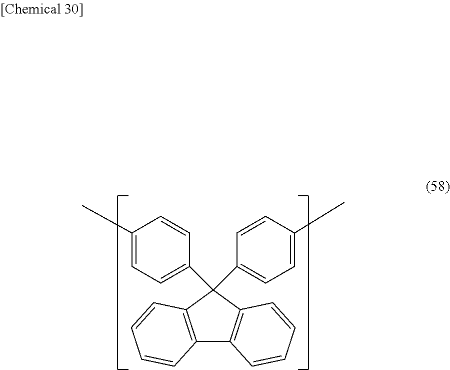

A group as the moiety other than the structure represented by the foregoing formula (58) (each of two groups respectively bonded at the both end parts (in the formula)) is a group represented by the foregoing formula (11).

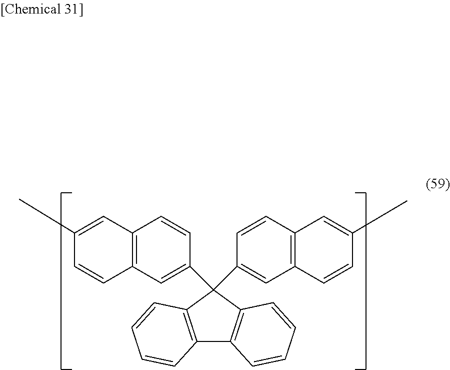

A group as the moiety other than the structure represented by the foregoing formula (59) (each of two groups respectively bonded at the both end parts (in the formula)) is a group represented by the foregoing formula (11).

A bisphenol A type epoxy resin (“850-S” available from DIC Corporation)

A biphenyl type epoxy resin (“NC-3000H” available from Nippon Kayaku Co., Ltd.)

A dicyclopentadiene type epoxy resin (“XD-1000” available from Nippon Kayaku Co., Ltd.)

A p-aminophenol type epoxy resin (“630” available from Mitsubishi Chemical Corporation)

A naphthalene skeleton type active ester compound (“EXB-9416-70BK” available from DIC Corporation, a methyl isobutyl ketone solution with a solid content of 70% by weight, the active ester compound has a naphthalene ring within a moiety other than the terminal)

A dicyclopentadiene skeleton type active ester compound (“HPC-8000-65T” available from DIC Corporation, a toluene solution with a solid content of 65% by weight, the active ester compound has no naphthalene ring within a moiety other than the terminal)

An aminotriazine novolac skeleton type phenol compound (“LA-1356” available from DIC Corporation, a methyl ethyl ketone solution with a solid content of 60% by weight)

A cyanate ester compound (“BA-3000S” available from Lonza Japan K.K., a methyl ethyl ketone solution with a solid content of 75% by weight)

An imidazole compound (“2P4MZ” available from SHIKOKU CHEMICALS CORPORATION)

A phenoxy resin (“YX6954-BH30” available from Mitsubishi Chemical Corporation, a 35% cyclohexanone and 35% methyl ethyl ketone solution with a solid content of 30% by weight)

A polyimide resin (“SN-20” available from New Japan Chemical Co., Ltd., an N-methyl-2-pyrrolidone (NMP) solution with a solid content of 20% by weight) A polyimide-containing liquid 1 (the solid content of 20% by weight) (synthesized in the following Synthesis Example 1)

### Synthesis Example 1

In a flask, 0.05 moles (8.51 g) of isophorone diamine and 0.05 moles (11.91 g) of bis(4-amino-3-methylcyclohexyl)methane as cycloaliphatic diamines were placed and 90 g of NMP (N-methylpyrrolidone) was added thereto.

Next, the flask was immersed in a dry ice-ethanol bath prepared by mixing dry ice and ethanol to be cooled to −78° C. Afterward, to the contents, 0.2 moles of acetic acid as a weak acid was slowly added dropwise through a dropping funnel while suppressing heat generation to mix the cycloaliphatic diamines and the weak acid. Afterward, the temperature of the contents was elevated to 23° C., with stirring under a nitrogen flow, 0.1 moles (52.05 g) of 4,4′-(4,4′-isopropylidenediphenoxy)diphthalic acid anhydride as a tetracarboxylic acid dianhydride and 30 g of NMP were added thereto, and the contents were stirred overnight at 23° C.

Next, 40 g of toluene was added to the contents, the temperature thereof was elevated, and the contents were heated at reflux for 2 hours while the temperature was kept at 190° C. and water was removed to the outside of the system in order to make the thermal imidization proceed. Afterward, the reaction solution was cooled to room temperature, added with 200 g of NMP to be diluted therewith, and added dropwise to a liquid mixture of water and an alcohol (water:an alcohol=9:1 (weight ratio)) to form a polymer. The produced polymer was filtered off, washed with water, and dried under vacuum to obtain a polymer. Peaks at 1700 cm⁻¹ and 1780 cm⁻¹ based on C═O expansion and contraction in an imide ring were confirmed by IR. To 10 g of this polymer, 20 g of methylcyclohexane and 20 g of cyclohexanone were added to obtain a polyimide containing liquid 1 (the solid content of 20% by weight). The molecular weight (weight average molecular weight) of the polyimide obtained was determined to be 24000.

GPC (Gel Permeation Chromatography) Measurement:

With the use of a high performance liquid chromatograph system available from SHIMADZU CORPORATION, the measurement was performed under conditions of a column temperature of 40° C. and a flow rate of 1.0 ml/minute using tetrahydrofuran (THF) as a developing solvent. As a detector, “SPD-10A” was used and two columns of “KF-804L” available from Shodex (SHOWA DENKO K.K.) (the elimination limit molecule quantity of 400,000) were connected in series to be used. As a standard polystyrene, “TSK standard polystyrene” available from Tosoh Corporation was adopted, substances of a weight average molecular weight Mw=354,000, 189,000, 98,900, 37,200, 17,100, 9,830, 5,870, 2,500, 1,050, or 500 were used to prepare a calibration curve, and the molecular weight was calculated.

A polyimide-containing liquid 2 (the solid content of 20% by weight) (synthesized in the following Synthesis Example 2)

### Synthesis Example 2

In a flask, 0.05 moles (8.51 g) of isophorone diamine and 0.05 moles (11.91 g) of bis(4-amino-3-methylcyclohexyl)methane as cycloaliphatic diamines were placed and 90 g of NMP (N-methylpyrrolidone) was added thereto.

Next, the flask was immersed in a dry ice-ethanol bath prepared by mixing dry ice and ethanol to be cooled to −78° C. Afterward, to the contents, 0.2 moles of acetic acid as a weak acid was slowly added dropwise through a dropping funnel while suppressing heat generation to mix the cycloaliphatic diamines and the weak acid. Afterward, the temperature of the contents was elevated to 23° C., with stirring under a nitrogen flow, 0.1 moles (24.82 g) of bicyclo[2.2.2]oct-7-ene-2,3,5,6-tetracarboxylic acid dianhydride as a tetracarboxylic acid dianhydride and 30 g of NMP were added thereto, and the contents were stirred overnight at 23° C.

Next, 40 g of toluene was added to the contents, the temperature thereof was elevated, and the contents were heated at reflux for 2 hours while the temperature was kept at 190° C. and water was removed to the outside of the system in order to make the thermal imidization proceed. Afterward, the reaction solution was cooled to room temperature, added with 200 g of NMP to be diluted therewith, and added dropwise to a liquid mixture of water and an alcohol (water:an alcohol=9:1 (weight ratio)) to form a polymer. The produced polymer was filtered off, washed with water, and dried under vacuum to obtain a polymer. Peaks at 1700 cm⁻¹ and 1780 cm⁻¹ based on C═O expansion and contraction in an imide ring were confirmed by IR. To 10 g of this polymer, 20 g of methylcyclohexane and 20 g of cyclohexanone were added to obtain a polyimide-containing liquid 2 (the solid content of 20% by weight). The molecular weight (weight average molecular weight) of the polyimide obtained was determined to be 21000.

Spherical silica (the average particle diameter of 0.5 μm, phenylaminosilane-treated, “SO-C2” available from Admatechs Company Limited)

Cyclohexanone

### Example 1

Five tenths parts by weight of a bisphenol A type epoxy resin (“850-S” available from DIC Corporation), 6.5 parts by weight of a biphenyl type epoxy resin (“NC-3000H” available from Nippon Kayaku Co., Ltd.), 0.7 parts by weight of a p-aminophenol type epoxy resin (“630” available from Mitsubishi Chemical Corporation), 2.9 parts by weight of a compound having a structure represented by the formula (51), 15.5 parts by weight of a naphthalene skeleton type active ester compound (“EXB-9416-70BK” available from DIC Corporation, a methyl isobutyl ketone solution with a solid content of 70% by weight), 1.8 parts by weight of an aminotriazine novolac skeleton type phenol compound (“LA-1356” available from DIC Corporation, a methyl ethyl ketone solution with a solid content of 60% by weight), 0.3 parts by weight of an imidazole compound (“2P4MZ” available from SHIKOKU CHEMICALS CORPORATION), 1.5 parts by weight of a phenoxy resin (“YX6954-BH30” available from Mitsubishi Chemical Corporation, a 35% by weight cyclohexanone and 35% by weight methyl ethyl ketone solution with a solid content of 30% by weight), 49.3 parts by weight of spherical silica (the average particle diameter of 0.5 μm, phenylaminosilane-treated “SO-C2”, available from Admatechs Company Limited), and 21.0 parts by weight of cyclohexanone were mixed and stirred at ordinary temperature until a homogeneous solution is attained to obtain a resin composition varnish.

With the use of an applicator, the resin composition varnish obtained was applied on a release-treated surface of a PET film subjected to a release treatment (“38X” available from LINTEC Corporation, 38 μm in thickness), and then, dried for 3 minutes in a gear oven at 100° C. to make the solvent volatilize. In this way, a resin film being formed on the PET film, having a thickness of 40 μm, and having a remaining amount of the solvent of 1.0% by weight or more and 4.0% by weight or less was obtained.

Both faces of a CCL (copper-clad laminate) substrate (“E679FG” available from Hitachi Chemical Company, Ltd.) were immersed in a copper surface roughening agent (“NEC etch BOND CZ-8100” available from MEC COMPANY LTD.) and the copper surface was subjected to a roughening treatment. Two sheets of laminated bodies composed of the PET film and the resin film obtained were set on both faces of the CCL substrate respectively so that the resin film side is put on the CCL substrate, and with the use of a diaphragm type vacuum laminator (“MVLP-500” available from MEIKI CO., LTD.), the two sheets were laminated on both faces of the CCL substrate respectively to obtain an uncured laminated product sample A. Lamination was performed in such a manner that the air pressure thereof was made 13 hPa or less by 20-second decompression, and the objects to be laminated were pressed for 20 seconds at 100° C. and a pressure of 0.8 MPa to perform the lamination.

In both faces of the uncured laminated product sample A, each PET film was peeled off from a resin film portion and both resin film portions were cured under the curing condition of 180° C. and 30 minutes to obtain a semi-cured laminated product sample.

Via Hole (Penetration Hole) Formation:

With the use of a CO₂ laser processing machine (available from Via Mechanics, Ltd.), a via hole (penetration hole) with a diameter of the upper end of 60 μm and a diameter of the lower end (bottom part) of 40 μm was formed in the semi-cured laminated product sample obtained. In this way, a laminated body B in which a semi-cured product of the resin film is layered on the substrate and a via hole (penetration hole) is formed in the semi-cured product of the resin film was obtained.

In a swelling liquid (an aqueous solution prepared with “Swelling Dip Securiganth P” available from Atotech Japan K.K. and “Sodium hydroxide” available from Wako Pure Chemical Industries, Ltd.) at 80° C., the laminated body B was immersed and shaken for 10 minutes at a swelling temperature of 80° C. Afterward, the laminated body B was washed with pure water.

In a roughening aqueous sodium permanganate solution (“Concentrate Compact CP” available from Atotech Japan K.K., “Sodium hydroxide” available from Wako Pure Chemical Industries, Ltd.) at 80° C., the swelling-treated laminated product sample was immersed and shaken for 30 minutes at a roughening temperature of 80° C. Afterward, the laminated product sample was washed for 10 minutes with a washing liquid (“Reduction Securiganth P” available from Atotech Japan K.K., “Sulfuric acid” available from Wako Pure Chemical Industries, Ltd.) at 40° C., and then, further washed with pure water to obtain a sample (1) for evaluation of residue removability at the bottom of a via hole.

### Examples 2 to 14 and Comparative Examples 1 to 4

With regard to Examples 2 to 14 and Comparative Examples 1 to 4, a resin composition varnish and a sample (1) for evaluation were obtained in the same manner as that in Example 1 except that a compound having a structure represented by each of the formulas (52) to (59) was used in place of the compound having a structure represented by the formula (51), and moreover, the kind of each ingredient and the blending amount thereof were set to those listed in the following Tables 2 to 4. With regard to Examples 2 to and Comparative Examples 1 to 3, a resin composition varnish and a sample (1) for evaluation were obtained in the same manner as that in Example 1 except for altering the compound having a structure represented by the formula (51) to a compound having a structure represented by each of the formulas (52) to (59).

(Evaluation)

(1) Residue Removability (Desmear Properties) at Bottom of Via Hole

The bottom part of a via hole in the sample (1) for evaluation was observed with a scanning electron microscope (SEM) to measure the maximum length of a smear from a wall surface of the bottom part of the via hole. The residue removability at the bottom of a via hole was judged according to the following criteria.

[Criteria for Judgment in Residue Removability at Bottom of Via Hole]

◯: The maximum length of a smear is less than 3 μm.

x: The maximum length of a smear is 3 μm or more.

(2) Heat Resistance

A resin film obtained was cured for 30 minutes at 180° C. and further cured for 120 minutes at 190° C. on the PET film to obtain a cured body. The cured body obtained was cut into a piece having a planar shape of 5 mm×3 mm. With the use of a viscoelasticity spectrorheometer (“RSA-II” available from RHEOMETRIC SCIENTIFIC FE, INC.), the cut piece of the cured body was measured for the loss rate tan δ under the condition of a temperature increasing rate of 5° C./minute from 30° C. to 250° C. to determine a temperature (glass transition temperature Tg) at which the loss rate tan δ becomes a maximum value.

(3) Dielectric Loss Tangent

A resin film obtained was cured for 30 minutes at 180° C. and further cured for 120 minutes at 190° C. on the PET film to obtain a cured body. The cured body obtained was cut into pieces with a size of 2 mm in width by 80 mm in length, 10 cut pieces thereof were stacked to form a stacked body with a thickness of 400 μm, and with the use of “Cavity resonance perturbation method-dielectric constant measuring apparatus CP521” available from Kanto Electronic Application and Development Inc. and “Network analyzer E83625” available from Agilent Technologies Japan, Ltd., the stacked body was measured for the dielectric loss tangent at ordinary temperature (23° C.) and at a measurement frequency of 5.8 GHz by a cavity resonance method.

(4) Peel Strength (90° Peel Strength):

In both faces of the above-mentioned uncured laminated product sample A, each PET film was peeled off from a resin film portion and both resin film portions were cured under the curing condition of 180° C. and 30 minutes to obtain a semi-cured laminated product sample.

In a swelling liquid (an aqueous solution prepared with “Swelling Dip Securiganth P” available from Atotech Japan K.K. and “Sodium hydroxide” available from Wako Pure Chemical Industries, Ltd.) at 60° C., the cured laminated product sample was immersed and shaken for 10 minutes at a swelling temperature of 60° C. Afterward, the laminated product sample was washed with pure water.

In a roughening aqueous sodium permanganate solution (“Concentrate Compact CP” available from Atotech Japan K.K., “Sodium hydroxide” available from Wako Pure Chemical Industries, Ltd.) at 80° C., the swelling-treated cured laminated product sample was immersed and shaken for 20 minutes at a roughening temperature of 80° C. Afterward, the laminated product sample was washed for 2 minutes with a washing liquid (“Reduction Securiganth P” available from Atotech Japan K.K., “Sulfuric acid” available from Wako Pure Chemical Industries, Ltd.) at 25° C., and then, further washed with pure water. In this way, on the CCL substrate in which an inner layer circuit was formed by etching, a roughening-treated cured product portion was formed.

The surface of the roughening-treated cured product portion was treated for 5 minutes with an alkaline cleaner (“Cleaner Securiganth 902” available from Atotech Japan K.K.) at 60° C. to be degreased and washed therewith. After washing, the cured product portion was treated for 2 minutes with a predip liquid (“Predip Neoganth B” available from Atotech Japan K.K.) at 25° C. Afterward, the cured product portion was treated for 5 minutes with an activator liquid (“Activator Neoganth 834” available from Atotech Japan K.K.) at 40° C. to be applied with a palladium catalyst. Next, the cured product portion was treated for 5 minutes with a reducing liquid (“Reducer Neoganth WA” available from Atotech Japan K.K.) at 30° C.

Next, the cured product portion was immersed in a chemical copper liquid (“Basic Printoganth MSK-DK”, “Kappa Printoganth MSK”, “Stabilizer Printoganth MSK”, and “Reducer Cu”, any of these is available from Atotech Japan K.K.) and subjected to electroless plating until the plating thickness becomes 0.5 μm or so. After electroless plating, in order to remove remaining hydrogen gas, the cured product portion was subjected to annealing for 30 minutes at a temperature of 120° C. Up to here, all processes including the electroless plating process were performed in respective beakers containing 2 L of a treatment liquid while the laminated product sample was shaken.

Next, the electroless plating-treated cured product portion was subjected to electrolytic plating until the plating thickness becomes 25 μm. With the use of a copper sulfate solution (“Copper sulfate pentahydrate” available from Wako Pure Chemical Industries, Ltd., “Sulfuric acid” available from Wako Pure Chemical Industries, Ltd., “Basic Leveler Caparacid HL” available from Atotech Japan K.K., “Correcting Agent Caparacid GS” available from Atotech Japan K.K.), the cured product portion was subjected to electrolytic plating as the electrolytic copper plating until the plating thickness becomes 25 μm or so while making an electric current of 0.6 A/cm² flow. After the copper plating treatment, the laminated product sample was heated for 90 minutes at 190° C. to further cure the cured product portion. In this way, a laminated product sample in which a copper plating layer is layered on an upper face of the cured product portion was obtained.

With regard to one surface of the obtained laminated product sample in which a copper plating layer is layered on the cured product portion, two notch lines being parallel to each other and apart from each other by 10 mm were formed in the copper plating layer. Afterward, with the use of a tensile testing machine (“AG-5000B” available from SHIMADZU CORPORATION), under the condition of a crosshead speed of 5 mm/minute, a cured product (insulating layer) portion and a metal layer (copper plating layer) portion were measured for the adhesive strength (90° peel strength). The peel strength was judged according to the following criteria.

[Criteria for Judgment in Peel Strength]

◯: The peel strength is 0.5 kgf/cm or more.

Δ: The peel strength is 0.4 kgf/cm or more and less than 0.5 kgf/cm.

x: The peel strength is less than 0.4 kgf/cm.

The details and the results are shown in the following Tables 2 to 4.

TABLE 2

| | | | Solid | | | | | | | |
|---|---|---|---|---|---|---|---|---|---|---|
| | | | content | | | | | | | |
| | | | weight | Example | Example | Example | Example | Example | Example | Example |
| | | | (%) | 1 | 2 | 3 | 4 | 5 | 6 | 7 |
| Compound having structure represented by | | | | Compound | Compound | Compound | Compound | Compound | Compound | Compound |
| formula (1) And kinds of other compounds | | | | (51) | (52) | (53) | (54) | (55) | (56) | (51) |
| Ingredients | Thermosetting | 850-S | 100 | 0.5 | 0.5 | 0.5 | 0.5 | 0.5 | 0.5 | 0.5 |
| to be | compounds | NC-3000H | 100 | 6.5 | 6.5 | 6.5 | 6.5 | 6.5 | 6.5 | 6.1 |
| blended | | XD-1000 | 100 | | | | | | | |
| (Parts by | | 630 | 100 | 0.7 | 0.7 | 0.7 | 0.7 | 0.7 | 0.7 | 0.7 |
| weight) | | Compound (51) | 100 | 2.9 | | | | | | 2.7 |
| | | Compound (52) | 100 | | 2.9 | | | | | |
| | | Compound (53) | 100 | | | 2.9 | | | | |
| | | Compound (54) | 100 | | | | 2.9 | | | |
| | | Compound (55) | 100 | | | | | 2.9 | | |
| | | Compound (56 | 100 | | | | | | 2.9 | |
| | | Compound (57) | 100 | | | | | | | |
| | | Compound (58) | 100 | | | | | | | |
| | | Compound (59) | 100 | | | | | | | |
| | Active ester | EXB-9416-70BK | 70 | 15.5 | 15.5 | 15.5 | 15.5 | 15.5 | 15.5 | 14.6 |
| | compounds | HPC-8000-65T | 65 | | | | | | | |
| | Other curing | LA-1356 | 60 | 1.8 | 1.8 | 1.8 | 1.8 | 1.8 | 1.8 | 1.7 |
| | agents | BA-3000S | 75 | | | | | | | |
| | Curing | 2P4MZ | 100 | 0.3 | 0.3 | 0.3 | 0.3 | 0.3 | 0.3 | 0.3 |
| | accelerator | | | | | | | | | |
| | Thermoplastic | YX6954-BH30 | 30 | 1.5 | 1.5 | 1.5 | 1.5 | 1.5 | 1.5 | |
| | resins | SN-20 | 20 | | | | | | | 5.4 |
| | | Polyimide-containing | 20 | | | | | | | |
| | | liquid 1 (Synthesis | | | | | | | | |
| | | Example 1) | | | | | | | | |
| | | Polyimide-containing | 20 | | | | | | | |
| | | liquid 2 (Synthesis | | | | | | | | |
| | | Example 2) | | | | | | | | |
| | Inorganic | SO-C2 | 100 | 49.3 | 49.3 | 49.3 | 49.3 | 49.3 | 49.3 | 48.0 |
| | filling | | | | | | | | | |
| | material | | | | | | | | | |
| | Solvent | Cyclohexanone | (Solvent) | 21.0 | 21.0 | 21.0 | 21.0 | 21.0 | 21.0 | 20.0 |
| Evaluation | | Desmear properties | | ∘ | ∘ | ∘ | ∘ | ∘ | ∘ | ∘ |
| | | Heat resistance | DMA-Tg | 184 | 183 | 184 | 185 | 183 | 192 | 185 |
| | | Dielectric loss | | 0.0041 | 0.0041 | 0.0039 | 0.0039 | 0.0042 | 0.0037 | 0.0038 |
| | | tangent (Df) | | | | | | | | |
| | | Peel strength | | ∘ | ∘ | ∘ | ∘ | ∘ | ∘ | ∘ |

TABLE 3

| | | | Solid | | | | | | |
|---|---|---|---|---|---|---|---|---|---|
| | | | content | | | | | | |
| | | | weight | Example | Example | Example | Example | Example | Example |
| | | | (%) | 8 | 9 | 10 | 12 | 13 | 14 |
| Compound having structure represented by | | | | Compound | Compound | Compound | Compound | Compound | Compound |
| formula (1) And kinds of other compounds | | | | (55) | (55) | (55) | (55) | (51) | (51) |
| Ingredients | Thermosetting | 850-S | 100 | 0.5 | 1.2 | 0.5 | 0.5 | 0.5 | 0.5 |
| to be | compounds | NC-3000H | 100 | | 6.5 | 6.5 | 3.5 | 6.1 | 6.1 |
| blended | | XD-1000 | 100 | 6.5 | | | | | |
| (Parts by | | 630 | 100 | 0.7 | | 0.7 | 0.7 | 0.7 | 0.7 |
| weight) | | Compound (51) | 100 | | | | | 2.7 | 2.7 |
| | | Compound (52) | 100 | | | | | | |
| | | Compound (53) | 100 | | | | | | |
| | | Compound (54) | 100 | | | | | | |
| | | Compound (55) | 100 | 2.9 | 2.9 | 2.9 | 5.8 | | |
| | | Compound (56 | 100 | | | | | | |
| | | Compound (57) | 100 | | | | | | |
| | | Compound (58) | 100 | | | | | | |
| | | Compound (59) | 100 | | | | | | |
| | Active ester | EXB-9416-70BK | 70 | 15.5 | 15.5 | | 15.5 | 14.6 | 14.6 |
| | compounds | HPC-8000-65T | 65 | | | 16.7 | | | |
| | Other curing | LA-1356 | 60 | 1.8 | 1.8 | 1.8 | 1.8 | 1.7 | 1.7 |
| | agents | BA-3000S | 75 | | | | | | |
| | Curing | 2P4MZ | 100 | 0.3 | 0.3 | 0.3 | 0.3 | 0.3 | 0.3 |
| | accelerator | | | | | | | | |
| | Thermoplastic | YX6954-BH30 | 30 | 1.5 | 1.5 | 1.5 | 1.5 | | |
| | resins | SN-20 | 20 | | | | | | |
| | | Polyimide-containing | 20 | | | | | 5.4 | |
| | | liquid 1 (Synthesis | | | | | | | |
| | | Example 1) | | | | | | | |
| | | Polyimide-containing | 20 | | | | | | 5.4 |
| | | liquid 2 (Synthesis | | | | | | | |
| | | Example 2) | | | | | | | |
| | Inorganic | SO-C2 | 100 | 49.3 | 49.3 | 49.3 | 49.3 | 48.0 | 48.0 |
| | filling | | | | | | | | |
| | material | | | | | | | | |
| | Solvent | Cyclohexanone | (Solvent) | 21.0 | 21.0 | 21.0 | 21.0 | 20.0 | 20.0 |
| Evaluation | | Desmear properties | | ∘ | Δ | ∘ | ∘ | ∘ | ∘ |
| | | Heat resistance | DMA-Tg | 188 | 182 | 185 | 189 | 186 | 182 |
| | | Dielectric loss | | 0.0047 | 0.0040 | 0.0048 | 0.0049 | 0.0036 | 0.0038 |
| | | tangent (Df) | | | | | | | |
| | | Peel strength | | Δ | Δ | Δ | ∘ | ∘ | Δ |

TABLE 4

| | | | Solid | | | | |
|---|---|---|---|---|---|---|---|
| | | | content | | | | |
| | | | weight | Comparative | Comparative | Comparative | Comparative |
| | | | (%) | Example 1 | Example 2 | Example 3 | Example 4 |
| Compound having structure represented by | | | | Compound | Compound | Compound | Compound |
| formula (1) And kinds of other compounds | | | | (57) | (58) | (59) | (51) |
| Ingredients | Thermosetting | 850-S | 100 | 0.5 | 0.5 | 0.5 | 0.5 |
| to be | compounds | NC-3000H | 100 | 6.5 | 6.5 | 6.5 | 6.5 |
| blended | | XD-1000 | 100 | | | | |
| (Parts by | | 630 | 100 | 0.7 | 0.7 | 0.7 | 0.7 |
| weight) | | Compound (51) | 100 | | | | 2.9 |
| | | Compound (52) | 100 | | | | |
| | | Compound (53) | 100 | | | | |
| | | Compound (54) | 100 | | | | |
| | | Compound (55) | 100 | | | | |
| | | Compound (56 | 100 | | | | |
| | | Compound (57) | 100 | 2.9 | | | |
| | | Compound (58) | 100 | | 2.9 | | |
| | | Compound (59) | 100 | | | 2.9 | |
| | Active ester | EXB-9416-70BK | 70 | 15.5 | 15.5 | 15.5 | |
| | compounds | HPC-8000-65T | 65 | | | | |
| | Other curing | LA-1356 | 60 | 1.8 | 1.8 | 1.8 | 1.8 |
| | agents | BA-3000S | 75 | | | | 14.5 |
| | Curing | 2P4MZ | 100 | 0.3 | 0.3 | 0.3 | 0.3 |
| | accelerator | | | | | | |
| | Thermoplastic | YX6954-BH30 | 30 | 1.5 | 1.5 | 1.5 | 1.5 |
| | resins | SN-20 | 20 | | | | |
| | | Polyimide-containing | 20 | | | | |
| | | liquid 1 (Synthesis | | | | | |
| | | Example 1) | | | | | |
| | | Polyimide-containing | 20 | | | | |
| | | liquid 2 (Synthesis | | | | | |
| | | Example 2) | | | | | |
| | Inorganic | SO-C2 | 100 | 49.3 | 49.3 | 49.3 | 49.3 |
| | filling | | | | | | |
| | material | | | | | | |
| | Solvent | Cyclohexanone | (Solvent) | 21.0 | 21.0 | 21.0 | 21.0 |
| Evaluation | | Desmear properties | | x | x | x | ∘ |
| | | Heat resistance | DMA-Tg | 183 | 182 | 191 | 189 |
| | | Dielectric loss | | 0.0041 | 0.0042 | 0.0037 | 0.0063 |
| | | tangent (Df) | | | | | |
| | | Peel strength | | Δ | Δ | Δ | Δ |

### EXPLANATION OF SYMBOLS

11: Multilayer substrate
12: Circuit substrate
12a: Upper face
13 to 16: Insulating layer
17: Metal layer

1. A resin composition, comprising:
a compound having a structure represented by the following formula (1), a structure in which a substituent is bonded to a benzene ring in the structure represented by the following formula (1), a structure represented by the following formula (2), a structure in which a substituent is bonded to a benzene ring in the structure represented by the following formula (2), a structure represented by the following formula (3), a structure in which a substituent is bonded to a benzene ring in the structure represented by the following formula (3), a structure represented by the following formula (4), or a structure in which a substituent is bonded to a benzene ring in the structure represented by the following formula (4); and
an active ester compound. 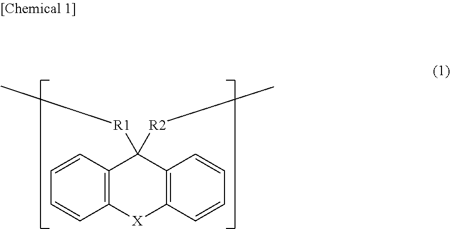
In the formula (1), R1 and R2 each represent a phenylene group or a naphthylene group and X represents a hetero atom, a group in which a hydrogen atom is bonded to a hetero atom, or a carbonyl group. 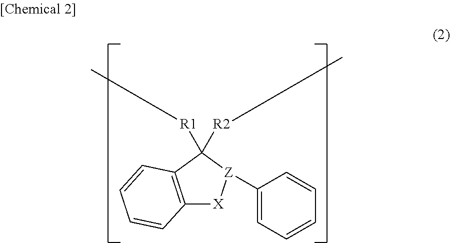
In the formula (2), R1 and R2 each represent a phenylene group or a naphthylene group, X represents a hetero atom, a group h which a hydrogen atom is bonded to a hetero atom, or a carbonyl group, and Z represents a CH group or an N group, 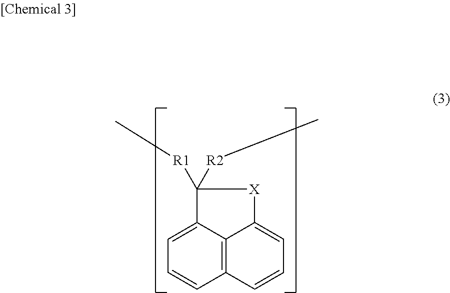
In the formula (3), R1 and R2 each represent a phenylene group or a naphthylene group and X represents a hetero atom, a group in which a hydrogen atom is bonded to a hetero atom, or a carbonyl group. 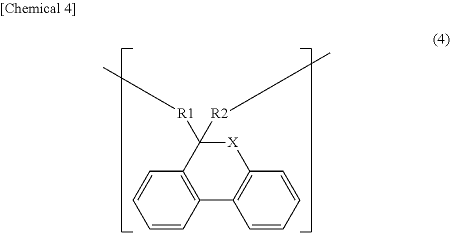
In the formula (4), R1 and R2 each represent a phenylene group or a naphthylene group and X represents a hetero atom, a group in which a hydrogen atom is bonded to a hetero atom, or a carbonyl group.

2. The resin composition according to claim 1, wherein the compound having a structure represented by the formula (1), a structure in which a substituent is bonded to a benzene ring in the structure represented by the formula (1), a structure represented by the formula (2), a structure in which a substituent is bonded to a benzene ring in the structure represented by the formula (2), a structure represented by the formula (3), a structure in which a substituent is bonded to a benzene ring in the structure represented by the formula (3), a structure represented by the formula (4), or a structure in which a substituent is bonded to a benzene ring in the structure represented by the formula (4) has an epoxy group within a moiety other than the structure represented by the formula (1), a moiety other than the structure in which a substituent is bonded to a benzene ring in the structure represented by the formula (1), a moiety other than the structure represented by the formula (2), a moiety other than the structure in which a substituent is bonded to a benzene ring in the structure represented by the formula (2), a moiety other than the structure represented by the formula (3), a moiety other than the structure in which a substituent is bonded to a benzene ring in the structure represented by the formula (3), a moiety other than the structure represented by the formula (4), or a moiety other than the structure in which a substituent is bonded to a benzene ring in the structure represented by the formula (4).

3. The resin composition according to claim 1, wherein the total content of the compound having a structure represented by the formula (1), a structure in which a substituent is bonded to a benzene ring in the structure represented by the formula (1), a structure represented by the formula (2), a structure in which a substituent is bonded to a benzene ring in the structure represented by the formula (2), a structure represented by the formula (3), a structure in which a substituent is bonded to a benzene ring in the structure represented by the formula (3), a structure represented by the formula (4), or a structure in which a substituent is bonded to a benzene ring in the structure represented by the formula (4) is 20% by weight or less in 100% by weight of ingredients excluding an inorganic filling material and a solvent from ingredients for the resin composition.

4. The resin composition according to claim 1, wherein the compound having a structure represented by the formula (1), a structure in which a substituent is bonded to a benzene ring in the structure represented by the formula (I), a structure represented by the formula (2), a structure in which a substituent is bonded to a benzene ring in the structure represented by the formula (2), a structure represented by the formula (3), a structure in which a substituent is bonded to a benzene ring in the structure represented by the formula (3), a structure represented by the formula (4), or a structure in which a substituent is bonded to a benzene ring in the structure represented by the formula (4) is a compound having a structure represented by the formula (1), a structure represented by the formula (2), a structure represented by the formula (3), or a structure represented by the formula (4).

5. The resin composition according to claim 1, further comprising:
an inorganic filling material.

6. The resin composition according to claim 1, further comprising:
a thermoplastic resin.

7. The resin composition according to claim 6, wherein the thermoplastic resin is a polyimide resin having an aromatic skeleton.

8. The resin composition according to claim 1, wherein the active ester compound has a naphthalene ring within a moiety other than the terminal.

9. A multilayer substrate, comprising:
a circuit substrate; and
an insulating layer arranged on the circuit substrate,
the insulating layer being a cured product of the resin composition according to claim 1.
